(19) United States
(12) Patent Application Publication
(10) Pub. No.: US 2023/0411520 A1
(43) Pub. Date: Dec. 21, 2023

(54) SEMICONDUCTOR STRUCTURE INCLUDING SEMICONDUCTOR DEVICES WITH DIFFERENT THRESHOLD VOLTAGES AND METHOD FOR MANUFACTURING THE SAME

(71) Applicant: TAIWAN SEMICONDUCTOR MANUFACTURING COMPANY, LTD., Hsinchu (TW)

(72) Inventors: Shen-Yang LEE, Hsinchu (TW); Chung-Liang CHENG, Hsinchu (TW); Hsiang-Pi CHANG, Hsinchu (TW); Chun-I WU, Hsinchu (TW); Huang-Lin CHAO, Hsinchu (TW); Pinyen LIN, Hsinchu (TW)

(73) Assignee: TAIWAN SEMICONDUCTOR MANUFACTURING COMPANY, LTD., Hsinchu (TW)

(21) Appl. No.: 17/751,340

(22) Filed: May 23, 2022

(51) Int. Cl. H01L 29/78; H01L 29/06; H01L 29/423; H01L 29/51; H01L 29/786; H01L 21/02; H01L 29/40; H01L 29/66

(52) U.S. Cl. CPC H01L 29/78391; H01L 29/0665; H01L 29/42392; H01L 29/516; H01L 29/66742; H01L 21/0259; H01L 29/401; H01L 29/6684; H01L 29/78696

(57) ABSTRACT

A semiconductor structure includes a plurality of semiconductor devices, each of which includes at least one channel layer, at least one interfacial layer, a gate dielectric layer, a gate electrode, and dipole elements. The at least one interfacial layer is disposed on the at least one channel layer. The gate dielectric layer is disposed over the at least one interfacial layer such that the at least one channel layer is separated from the gate dielectric layer through the at least one interfacial layer. The gate electrode is disposed on the gate dielectric layer. The dipole elements are present in the interfacial layer of at least one of the semiconductor devices in a predetermined amount such that the at least one of the semiconductor devices has a tunability of threshold voltage from that of the other of the semiconductor devices. Methods for manufacturing the semiconductor structure are also disclosed.

### BACKGROUND

Transistors are key active components in modern integrated circuits (IC). With rapid development of semiconductor technology, critical dimension (CD) of transistors keeps shrinking and various three-dimensional (3D) transistor structures are springing up, making it possible to integrate a large number of transistors per unit area. In addition, transistors in IC may have multiple specifications (e.g., threshold voltage, saturation current, off-current, etc.) according to variety of IC circuit design. Therefore, a 3D structure for advanced node transistors with multiple specifications and/or a method for manufacturing such 3D structure is in continuous development. Achievement of multiple threshold voltage is one of key knobs for serving different customers with various circuit design.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 25 illustrate schematic views of intermediate stages of the method depicted in FIG. 1 in accordance with some embodiments.

FIG. 26 is a flow diagram illustrating another method for manufacturing a semiconductor structure in accordance with some embodiments.

FIGS. 27 to 37 illustrate schematic views of the intermediate stages of the method depicted in FIG. 26 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, a chip includes a plurality of semiconductor devices with different threshold voltages according to customized requirements. In advanced technology nodes, threshold voltage of each of the semiconductor devices may be controlled by material selection of work function metal layer(s) disposed on a gate dielectric layer opposite to a channel layer, by adjusting thickness of the work function metal layer(s), or by changing concentration of impurities in the channel layer. For semiconductor devices with a gate-all-around (GAA) structure, each of which includes a plurality of the channel layers separated from each other, controlling the concentration of impurities in each of the channel layers to be the same as each other by an ion implantation process is a challenge. Furthermore, along with the dimensional shrinkage of the semiconductor devices, the spacing between two adjacent ones of the channel layers may be insufficient to fill the work function metal layer(s) with a predetermined thickness, causing a relatively low threshold voltage difficult to be achieved. The present disclosure is directed to a semiconductor structure including a plurality of semiconductor devices which may have different values of threshold voltage (Vt), and which have the same thickness of work function metal layer(s), and a method for manufacturing the same. The semiconductor structure may be applied to planar field effect transistors (FET), fin-type FETs (FinFET), multi-gate FETs (e.g., GAA FETs), multi-bridge channel FETs (MBCFET), fork-sheet FETs, etc.), or other suitable devices. The method of the present disclosure is extremely advantageous for the multi-gate FETs, and may be applied to the planar FETs, as well as the FinFETs.

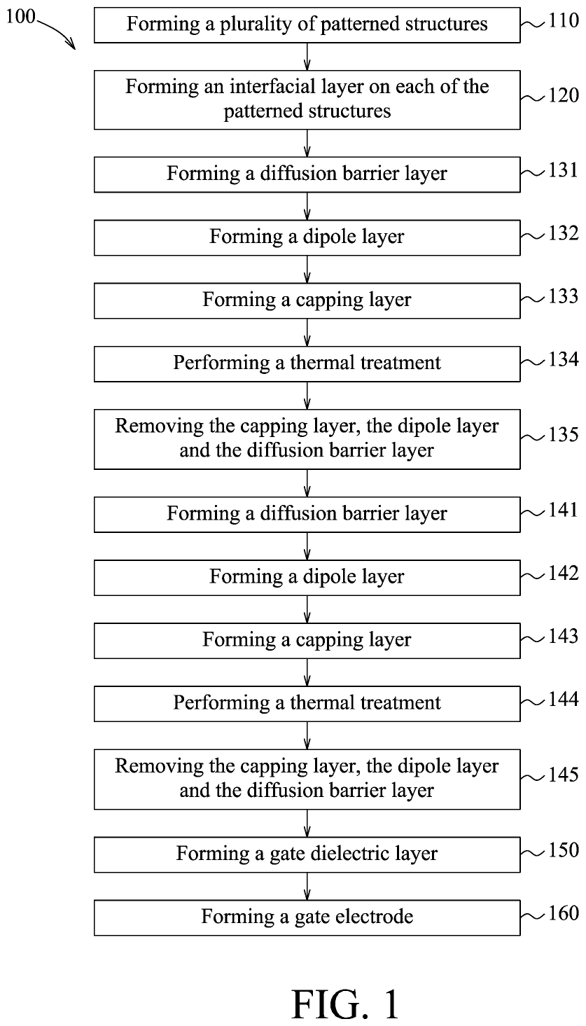

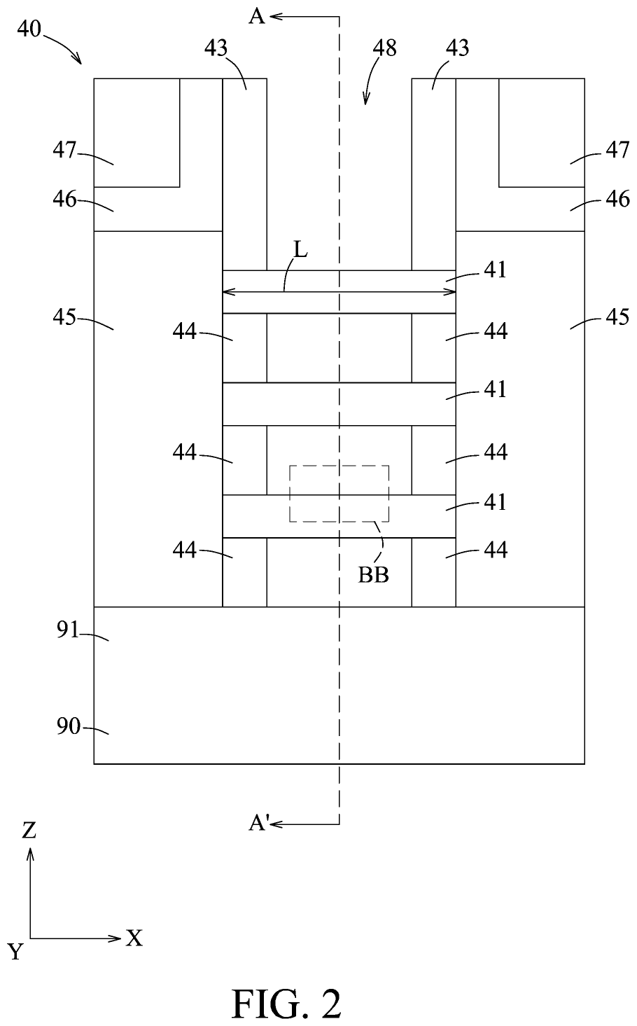

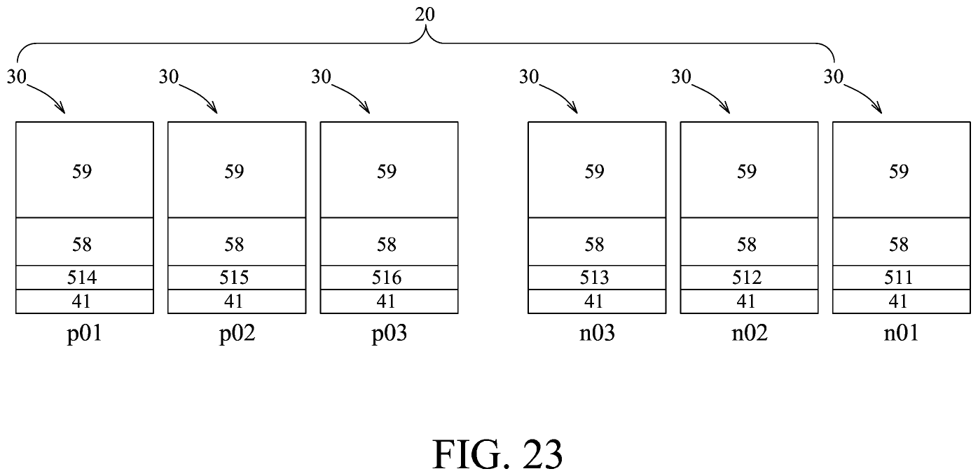

FIG. 1 is a flow diagram illustrating a method 100 for manufacturing a semiconductor structure (for example, the semiconductor structure 20 shown in FIG. 23) in accordance with some embodiments. FIGS. 2 to 25 illustrate schematic views of intermediate stages of the method 100 in accordance with some embodiments.

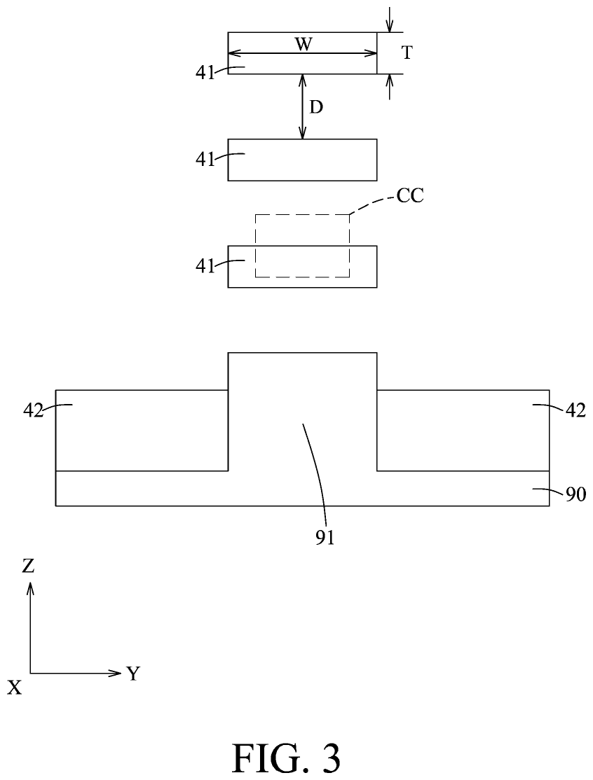

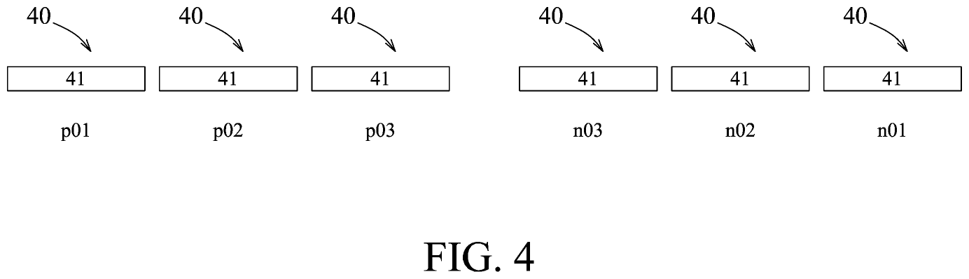

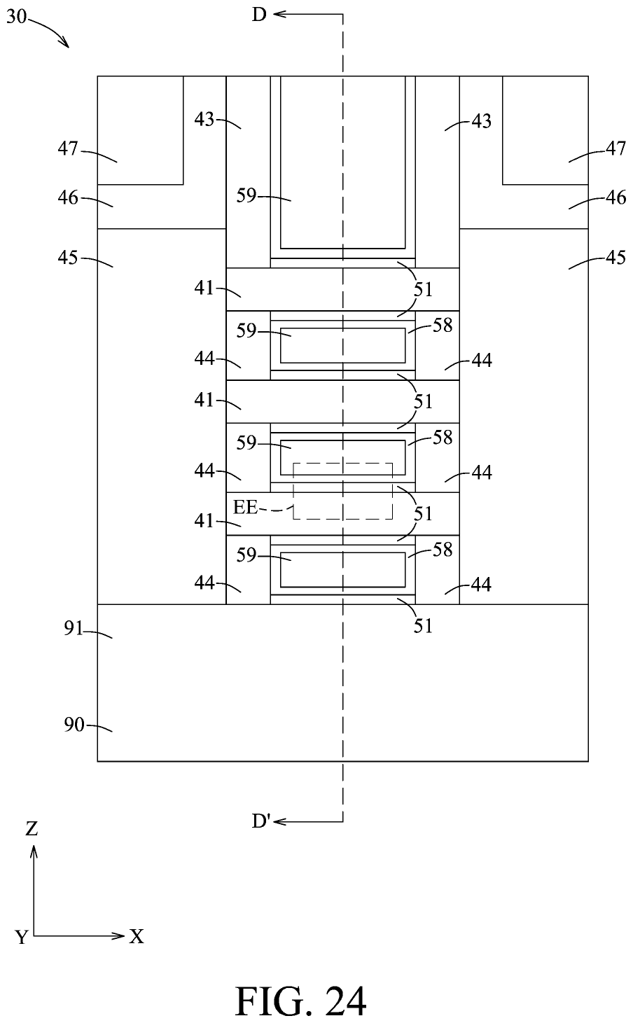

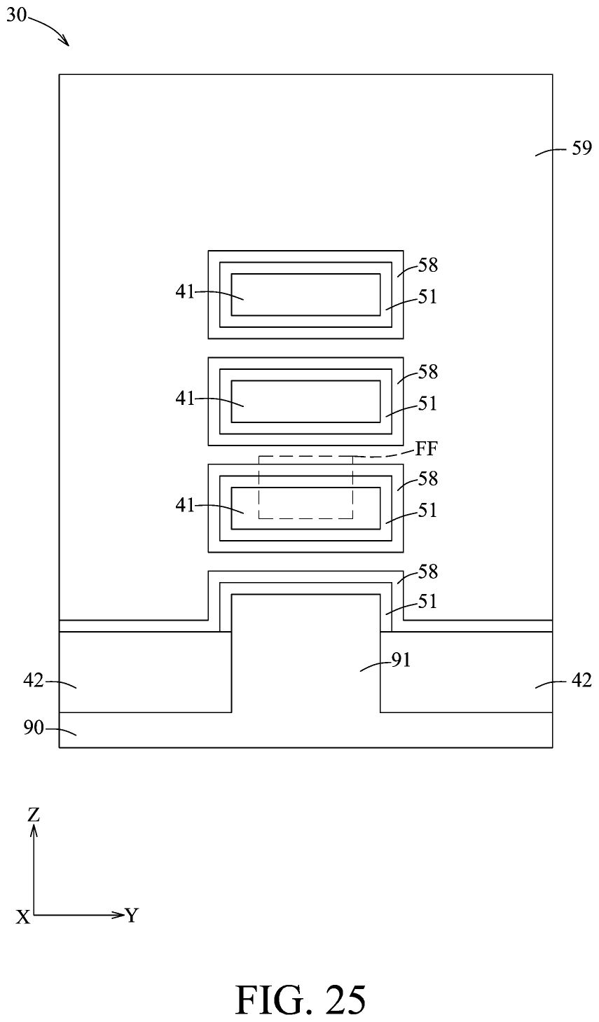

Referring to FIG. 1 and the examples illustrated in FIGS. 2 to 4, the method 100 begins at step 110, where a plurality of patterned structures 40 are formed. FIG. 2 is a schematic sectional view of one of the patterned structures 40 in accordance with some embodiments. FIG. 3 is a schematic sectional view of the one of the patterned structures 40 taken long line A-A′ of FIG. 2. FIG. 4 is a schematic view illustrating regions BB of the patterned structures 40 (each being shown in FIG. 2) or regions CC of the patterned structures 40 (each being shown in FIG. 3). It should be noted that although the method 100 is exemplified using a method for manufacturing a GAA structure including a plurality of GAA devices (one of which is exemplified by the semiconductor device 30 shown in FIGS. 24 and 25), the method 100 may be used for manufacturing other suitable structures.

As shown in FIGS. 2 and 3, the patterned structures 40 (one of which is shown) are formed on a semiconductor substrate 90. In some embodiments, the semiconductor substrate 90 includes first, second and third p-type regions p01, p02, p03, and first, second and third n-type regions n01, n02, n03, i.e., six of the patterned structures 40 are to be respectively formed thereon, as shown in FIG. 4. The number of the patterned structures 40 or the number of the semiconductor devices 30 to be subsequently and respectively formed from the patterned structures 40 can be varied according to the circuit design of the semiconductor structure 20 (see FIG. 25).

Each of the patterned structures 40 includes at least one channel layer 41. In some embodiments, each of the patterned structures 40 includes a plurality of channel layers 41 separated from each other in a Z direction. For example, as shown in FIGS. 2 and 3, the number of the channel layers 41 in each of the patterned structures 40 is three, but is not limited thereto. With continuous shrinkage of the scale of the semiconductor devices 30, a distance (D) between two adjacent ones of the channel layers 41 in the Z direction in each of the patterned structures 40 becomes smaller. In some embodiments, two adjacent ones of the channel layers 41 are separated from each other by the distance (D) ranging from about 4 nm to about 12 nm. In some embodiments, each of the channel layers 41 may have a thickness (T) in the Z direction, and the thickness (T) ranges from about 5 nm to about 8 nm. In some embodiments, each of the channel layers 41 may have a width (W) in a Y direction transverse to the Z direction or a length (L) in an X direction transverse to the Y and Z direction, and each of the width (W) and the length (L) ranges from about 15 nm to about 50 nm. In some not-shown embodiments, when the method 100 is used for manufacturing a FinFET structure including a plurality of the FinFET devices, the patterned structures for forming the FinFET devices each includes a single channel layer, and the channel layers of the patterned structures may also be denoted by the numeral 41 shown in FIG. 4. In some embodiments, the semiconductor substrate 90 may be made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The material for forming the semiconductor substrate 90 may be doped with p-type impurities or n-type impurities, or undoped. In addition, the semiconductor substrate 90 may be a bulk silicon substrate, a silicon-on-insulator (SOI) substrate, or a germanium-on-insulator (GOI) substrate. Other suitable materials for the semiconductor substrate 90 are within the contemplated scope of the present disclosure. In some embodiments, the channel layers 41 of the patterned structures 40 may be made from a material the same or different from that of the semiconductor substrate 90. Since suitable materials for the channel layers 41 are similar to those for the semiconductor substrate 90, the details thereof are omitted for the sake of brevity.

In some embodiments, as shown in FIGS. 2 and 3, each of the patterned structures 40 (one of which is shown) further includes two isolation portions 42, two gate spacers 43, a plurality of inner spacers 44, two source/drain portions 45, two contact etching stop layers (CESL) 46, and two interlayer dielectric (ILD) layers 47.

In some embodiments, each of the patterned structures 40 may be formed by (i) patterning a substrate and a stack (not shown) formed thereon to form a fin structure on the semiconductor substrate 90 (the substrate is patterned into the semiconductor substrate 90 and a lower portion 91 of the fin structure, and the stack is patterned into an upper portion of the fin structure including a plurality of sacrificial films and a plurality of channel films disposed to alternate with the sacrificial films), (ii) forming an isolation layer over the semiconductor substrate 90 and the fin structure followed by a planarization process, for example, but not limited to, chemical mechanism polishing (CMP), to form isolation regions at two opposite sides of the fin structure, (iii) recessing the isolation regions to form the isolation portions 42 so as to expose the upper portion of the fin structure and an upper part of the lower portion 91 of the fin structure, (iv) forming a dummy gate portion (not shown) over the fin structure such that the fin structure has two portions exposed from the dummy gate portion and located at two opposite sides of the dummy gate portion in the X direction, (v) forming the gate spacers 43 at two opposite sides of the dummy gate portion, (vi) etching the exposed portions of the fin structure to form source/drain recesses (not shown), such that the channel films are patterned into the channel layers 41 and the sacrificial films are patterned into sacrificial layers (not shown), (vii) recessing the sacrificial layers through the source/drain recesses to form recesses, (viii) forming the inner spacers 44 in the recesses to cover the remaining sacrificial layers, (ix) forming the source/drain portions 45 respectively in the source/drain recesses, such that each of the channel layers 41 extends between the source/drain portions 45, (x) forming the CESL 46 and the ILD layers 47 on the source/drain portions 45, and (xi) removing the dummy gate portion and the remaining sacrificial layers using a wet etching process or other suitable processes to form a cavity 48. Other suitable processes for forming the patterned structures 40 are within the contemplated scope of the present disclosure.

The channel film in the fin structure is made of a material that is the same as that of the channel layer 41. The sacrificial film in the fin structure may include a material that is different from that of the channel film, so that the sacrificial layer formed from the sacrificial film can be selectively removed and the channel layer 41 is substantially not removed. Suitable materials for forming the sacrificial film are similar to those for forming the channel layer 41, and thus details of possible materials for the sacrificial film are omitted for the sake of brevity.

The isolation portions 42 are provided for isolating two adjacent ones of the patterned structures 40. The isolation portions 42 may each be a portion of a shallow trench isolation (STI), a deep trench isolation (DTI), or other suitable structures, and may be made of an oxide material (for example, silicon oxide), a nitride material (for example, silicon nitride), or a combination thereof. Other suitable materials for the isolation portions 42 are within the contemplated scope of the present disclosure.

The dummy gate portion may include a dummy gate dielectric formed on the fin structure, a dummy gate electrode formed on the dummy gate dielectric opposite to the fin structure, and a hard mask formed on the dummy gate electrode opposite to the dummy gate dielectric. In some embodiments, the hard mask may include silicon nitride, silicon oxide, silicon oxynitride, or combinations thereof, the dummy gate electrode may include polycrystalline silicon, single crystalline silicon, amorphous silicon, or combinations thereof, and the dummy gate dielectric may include silicon oxide, silicon nitride, silicon oxynitride, high dielectric constant (k) materials, or combinations thereof. Other suitable materials for the dummy gate portion are within the contemplated scope of the present disclosure.

Each of the gate spacers 43, the inner spacers 44, the CESL 46, and the ILD layers 47 may include silicon oxide, silicon nitride, silicon oxynitride, or combinations thereof. Other suitable materials for the gate spacers 43, the inner spacers 44, the CESL 46, and the ILD layers 47 are within the contemplated scope of the present disclosure.

The source/drain portions 45 may be doped with an n-type impurity or a p-type impurity, and may be formed as a single layer structure or a multi-layered structure having several sub-layers with different doping concentration. For example, in some embodiments, the source/drain portions 45 at each of the first, second and third p-type regions p01, p02, p03 (see FIG. 4) may have a conductivity type different from those at each of the first, second and third n-type regions n01, n02, n03 (see FIG. 4). In some embodiments, each of the source/drain portions 45 at each of the first, second and third p-type regions p01, p02, p03 has a p-type conductivity, and includes single crystalline or polycrystalline silicon, single crystalline or polycrystalline silicon germanium, or other suitable materials doped with a p-type impurity so as to function as a source/drain of a p-FET. The p-type impurity may be, for example, but not limited to, boron (B), aluminum (Al), gallium (Ga), indium (In), other suitable materials, or combinations thereof. In some embodiments, each of the source/drain portions 45 at each of the first, second and third n-type regions n01, n02, n03 has an n-type conductivity, and includes single crystalline silicon, polycrystalline silicon or other suitable materials doped with an n-type impurity so as to function as a source/drain of an n-FET. The n-type impurity may be, for example, but not limited to, nitrogen (N), phosphorous (P), arsenic (As), antimony (Sb), other suitable materials, or combinations thereof. In some embodiments, the conductivity types of the source/drain portions 45 at each of the first, second and third p-type regions p01, p02, p03 and at each of the first, second and third n-type regions n01, n02, n03 may be swapped, that is, the source/drain portions 45 at each of the first, second and third p-type regions p01, p02, p03 have an n-type conductivity, and the source/drain portions 45 at each of the first, second and third n-type regions n01, n02, n03 have a p-type conductivity. It is noted that each of the source/drain portions 45 may refer to a source or a drain, individually or collectively dependent upon the context.

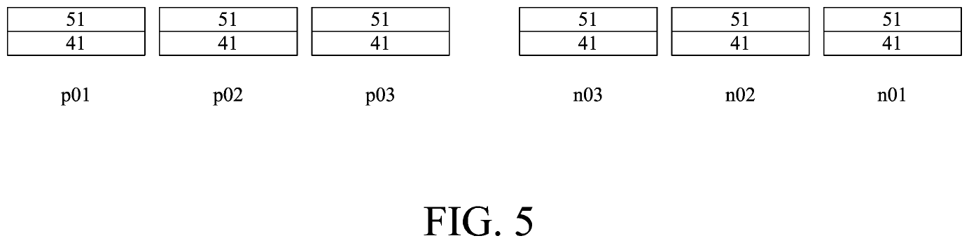

For purposes of simplicity and clarity, in FIGS. 5 to 21, at each of the first, second and third p-type regions p01, p02, p03, and the first, second and third n-type regions n01, n02, n03, an upper portion of one of the channel layers 41 and element(s) formed thereon are shown and described below, while other elements are omitted.

Referring to FIG. 1 and the example illustrated in FIG. 5, the method 100 proceeds to step 120, where at each of the patterned structures 40 of the first, second and third p-type regions p01, p02, p03, and the first, second and third n-type regions n01, n02, n03, an interfacial layer 51 is formed on the channel layer 41. In some embodiments, at each of the regions p01, p02, p03, n01, n02, n03, the interfacial layer 51 is formed around the channel layer 41 (see FIG. 25). In some embodiments, at each of the regions p01, p02, p03, n01, n02, n03, the interfacial layer 51 may be formed on upper and side surfaces of the lower portion 91 (see FIGS. 24 and 25) of the fin structure. The interfacial layer 51 may serve as a buffer layer for facilitating growth of a layer to be subsequently formed thereon, and may include an insulating material. The insulating material includes silicon oxide, silicon nitride, silicon oxynitride, or combinations thereof. Other suitable materials for the interfacial layer 51 are within the contemplated scope of the present disclosure. In some embodiments, the interfacial layer 51 has a thickness ranging from about 5 Å to about 20 Å. In some embodiments, the interfacial layer 51 is formed using chemical vapor deposition (CVD), atomic layer deposition (ALD), thermal oxidation, or wet chemical oxidation. Other suitable techniques for forming the interfacial layer 51 are within the contemplated scope of the present disclosure. In some embodiments, formation of the interfacial layer 51 further includes a cleaning process for surface treatment of the interfacial layer 51 after deposition thereof. In some embodiments, the cleaning process may include a step of standard clean 1 (SC1), a step of standard clean 2 (SC2), and a cleaning step using ozonated deionized wafer. In some embodiments, the step of SC1 is performed using a solution including mixture of ammonia water and hydrogen peroxide water. In some embodiments, the step of SC2 is performed using a solution including mixture of hydrochloric acid and hydrogen peroxide water. Other suitable cleaning processes suitable for treating the interfacial layer 51 are within the contemplated scope of the present disclosure.

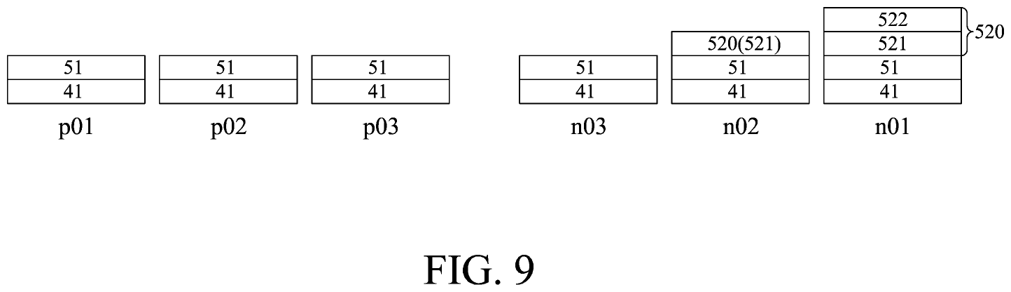

Referring to FIG. 1 and the example illustrated in FIG. 9, the method 100 proceeds to step 131, where a diffusion barrier layer 520 is formed on the interfacial layers 51 on the structure at the first and second n-type regions n01, n02, and a thickness of the diffusion barrier layer 520 at the first n-type region n01 is greater than that of the diffusion barrier layer 520 at the second n-type region n02. With the diffusion barrier layer 520 having a predetermined thickness, amounts of first dipole elements (described below) diffusing into the interfacial layer 51 at each of first and second n-type regions n01, n02 can be controlled. In some embodiments, the diffusion barrier layer 520 is made of a material that is chemically and thermally stable at a temperature higher than that of a thermal annealing process to be performed subsequently, so that thermal decomposition of the diffusion barrier layer 520 is less likely to occur, and elements or atoms in the diffusion barrier layer 520 may not diffuse into the interfacial layer 51 during the thermal annealing process. In some embodiments, the diffusion barrier layer 520 includes an oxide, a nitride, a carbide, an oxynitride, an oxycarbide, a carbonitride, an oxycarbonitride, a metal oxide, a metal nitride, a metal carbide, a metal oxynitride, or combinations thereof. In some embodiments, the diffusion barrier layer 520 may be made of silicon oxide, silicon nitride, aluminum oxide, aluminum nitride, titanium nitride, silicon oxynitride, silicon carbide, silicon oxycarbide, but is not limited thereto. Other materials suitable for forming the diffusion barrier layer 520 are within the contemplated scope of the present disclosure.

In some embodiments, step 131 includes sub-steps 13A to 13D.

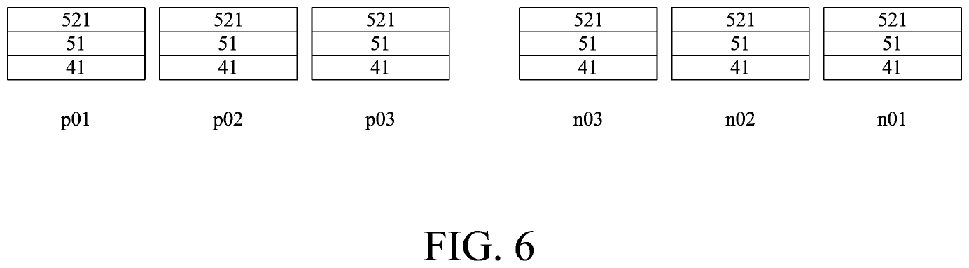

Referring the example illustrated in FIG. 6, in sub-step 13A, at each of the first, second and third p-type regions p01, p02, p03, and the first, second and third n-type regions n01, n02, n03, a diffusion sub-layer 521 is formed on the interfacial layer 51 using CVD, ALD, or other suitable deposition techniques. In some embodiments, the diffusion sub-layer 521 may also be formed on the inner spacers 44 (see FIG. 2) of the patterned structures 40 at the regions p01, p02, p03, n01, n02, n03. Suitable materials for forming the diffusion sub-layer 521 are similar to those for forming the diffusion barrier layer 520, and thus details of the possible materials for the diffusion sub-layer 521 are omitted for the sake of brevity. In some embodiments, the diffusion sub-layer 521 has a thickness ranging from about 5 Å to about 50 Å.

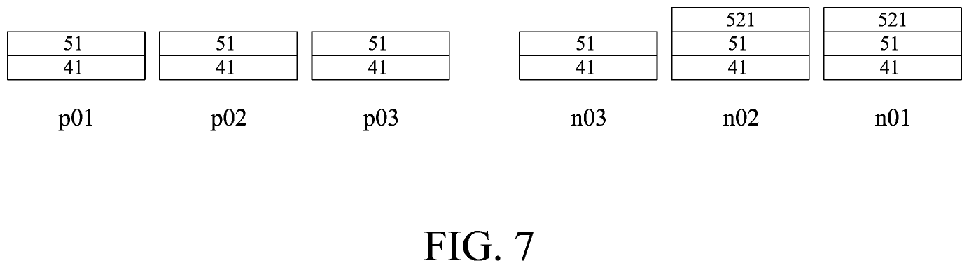

Referring the example illustrated in FIGS. 6 and 7, in sub-step 13B, the diffusion sub-layer 521 at each of the first, second and third p-type regions p01, p02, p03, and the third n-type region n03 is removed, while the diffusion sub-layer 521 at each of the first and second n-type regions n01, n02 is retained. In some embodiments, sub-step 13B includes (i) forming a photoresist layer and/or a hard mask layer (not shown) on the diffusion sub-layer 521 at each of the first, second and third p-type regions p01, p02, p03, and the first, second and third n-type regions n01, n02, n03 as shown in FIG. 6, using, for example, but not limited to, spin coating, (ii) patterning the photoresist layer and/or the hard mask layer to expose the diffusion sub-layer 521 at each of the regions p01, p02, p03, n03 using, for example, but not limited to, exposure and developing processes, (iii) removing the diffusion sub-layer 521 at each of the regions p01, p02, p03, n03 using, for example, but not limited to, a wet etching process and/or a dry etching process, and (iv) removing the patterned photoresist layer and/or the patterned hard mask layer using, for example, but not limited to, a stripping process and/or an etching process. In some embodiments, the wet etching process applied for removal of the diffusion sub-layer 521 may include use of a solution containing a wet etchant (i.e., a wet etchant solution). The wet etchant solution has a higher etching selectivity (or higher etching rate) over the diffusion sub-layer 521 than the interfacial layer 51 and/or the inner spacers 44 (see FIG. 2) so that the interfacial layer 51 and/or the inner spacers 44 are substantially not removed. In some embodiments, the wet etchant solution may include NH₄OH, H₂SO₄, H₂O₂, HCl, H₂O, HF, HNO₃, diluted HF, O₃, H₃PO₄, or the like, or combinations thereof, but is not limited thereto. Other chemical solutions suitable for removing the diffusion sub-layer 521 are within the contemplated scope of the present disclosure. In some embodiments, parameter(s) of the etching process (e.g., temperature and concentration of the wet etchant solution, and so on) can be adjusted so that the diffusion sub-layer 521 is well removed.

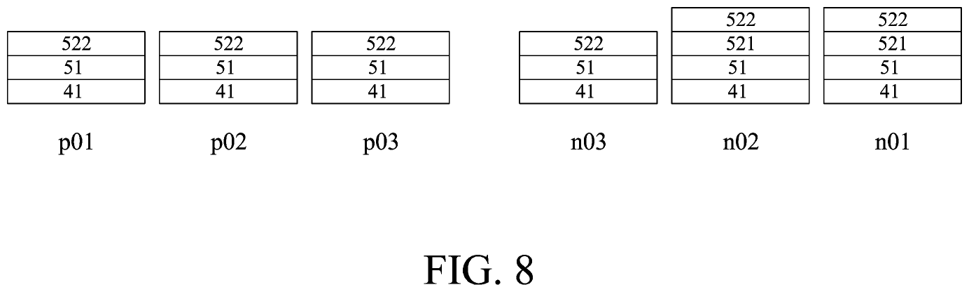

Referring the example illustrated in FIG. 8, in sub-step 13C, an additional diffusion sub-layer 522 is formed on the structure at each of the first, second and third p-type regions p01, p02, p03, and the first, second and third n-type regions n01, n02, n03 as shown in FIG. 7 using CVD, ALD, or other suitable deposition techniques. In some embodiments, the additional diffusion sub-layer 522 may also be formed on the inner spacers 44 (see FIG. 2) of the patterned structure 40 at each of the regions p01, p02, p03, n03. The materials, range of thickness, and configurations for the additional diffusion sub-layer 522 are similar to those for the diffusion sub-layer 521, and thus details thereof are omitted for the sake of brevity.

Referring the examples illustrated in FIGS. 8 and 9, in sub-step 13D, the additional diffusion sub-layer 522 at each of the first, second and third p-type regions p01, p02, p03, and the second and third n-type regions n02, n03 is removed, while the additional diffusion sub-layer 522 at the first n-type region n01 is retained. In some embodiments, sub-step 13D includes (i) forming a photoresist layer and/or a hard mask layer (not shown) on the additional diffusion sub-layer 522 at each of the first, second and third p-type regions p01, p02, p03, and the first, second and third n-type regions n01, n02, n03 as shown in FIG. 8, using, for example, but not limited to, spin coating, (ii) patterning the photoresist layer and/or the hard mask layer to expose the additional diffusion sub-layer 522 at each of the regions p01, p02, p03, n02, n03 using, for example, but not limited to, exposure and developing processes, (iii) removing the additional diffusion sub-layer 522 at each of the regions p01, p02, p03, n02, n03 using, for example, but not limited to, a wet etching process or a dry etching process, and (iv) removing the patterned photoresist layer and/or the patterned hard mask layer using, for example, but not limited to, a stripping process and/or an etching process. In some embodiments, the wet etching process applied for removal of the additional diffusion sub-layer 522 may include use of a wet etchant solution similar to the wet etchant solution used in sub-step 13B, and thus details thereof are omitted for sake of the brevity. In addition, the wet etching process in sub-step 13D may be a time-controlled etching process so that the etching is stopped after a period of time so as to prevent the diffusion sub-layer 521 formed beneath the additional diffusion sub-layer 522 at the second n-type region n02 from being removed during sub-step 13D.

After sub-step 13D, as shown in FIG. 9, the diffusion barrier layer 520 at the first n-type region n01 includes two sub-layers (i.e., the diffusion sub-layer 521 and the additional diffusion sub-layer 522), the diffusion barrier layer 520 at the second n-type region n02 includes one sub-layer (i.e., the diffusion sub-layer 521). In addition, the diffusion barrier layer 520 is not formed at the first, second and third p-type regions p01, p02, p03, and the third n-type region n03. In some embodiments, the number of the sub-layers (i.e., the thickness of the diffusion barrier layer 520) on the interfacial layer 51 at each of the regions p01, p02, p03, n01, n02, n03 can be varied according to desired amounts of the first dipole elements (to be described hereinafter) to be diffused into the corresponding interfacial layer 51, and according to a space available for film deposition between two adjacent ones of the channel layers 41 in the corresponding patterned structure 40 (see FIGS. 2 and 3).

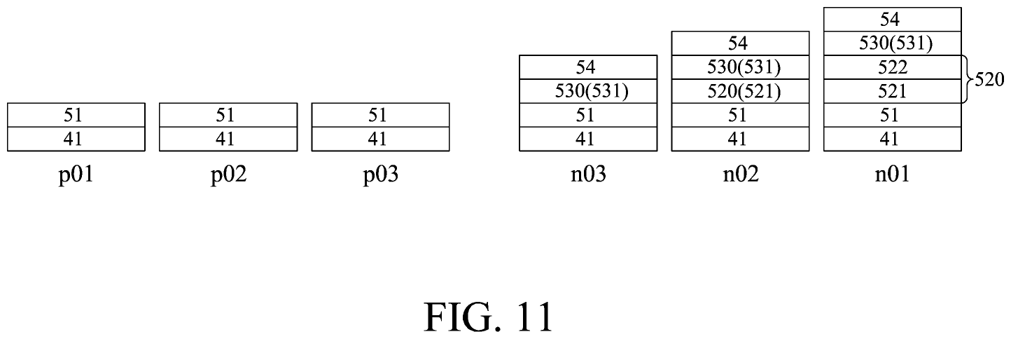

Referring to FIG. 1 and the example illustrated in FIG. 11, the method 100 proceeds to step 132, where a dipole layer 530 is formed on the structure at each of the first, second and third n-type regions n01, n02, n03 as shown in FIG. 9. The dipole layer 530 serves as a source that provides the first dipole elements to be diffused into the interfacial layer 51, and thus the dipole layer 530 includes the first dipole elements. In some embodiments, the first dipole elements includes zinc (Zn), gallium (Ga), lanthanum (La), magnesium (Mg), or combinations thereof. In some embodiments, the dipole layer 530 includes an oxide, a nitride, a carbide, an oxynitride, an oxycarbide, a carbonitride, an oxycarbonitride, a metal oxide, a metal nitride, a metal carbide, a metal oxynitride, or combinations thereof, each of which contains the abovementioned first dipole elements. For example, when lanthanum is selected as the first dipole elements, the dipole layer 530 may be made of lanthanum oxide, lanthanum nitride, lanthanum oxynitride, but is not limited thereto. Other materials suitable for forming the dipole layer 530 are within the contemplated scope of the present disclosure.

Referring to FIG. 1 and the example illustrated in FIG. 11, the method 100 proceeds to steps 133, where at each of the first, second and third n-type regions n01, n02, n03, a capping layer 54 is formed on the dipole layer 530 opposite to the interfacial layer 51. The capping layer 54 is provided to stabilize chemical properties of the dipole layer 530 at each of the regions n01, n02, n03 during a thermal annealing process to be performed subsequently. For example, the capping layer 54 may prevent decomposition of the corresponding dipole layer 530, or prevent the first dipole elements from escaping from an outer surface of the corresponding dipole layer 530 in a direction away from the corresponding interfacial layer 51 (i.e., outward diffusion). In some embodiments, the capping layer 54 may be made of a material that is similar to those for forming the diffusion barrier layer 520, so that thermal decomposition of the capping layer 54 is less likely to occur, and elements or atoms in the capping layer 54 may not diffuse into the interfacial layer 51 during the thermal annealing process. Other possible materials for the capping layer 54 are within the contemplated scope of the present disclosure.

In some embodiments, formation of the dipole layer 530 and the capping layer 54 (i.e., steps 132 and 133) may include sub-steps 13E to 13G.

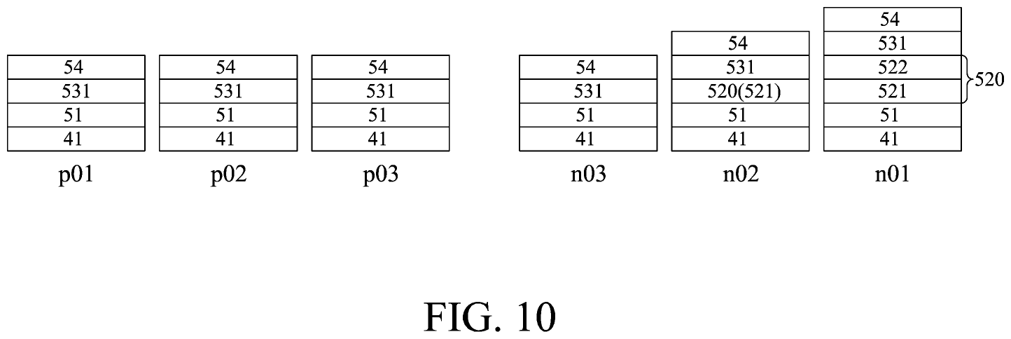

Referring the examples illustrated in FIG. 10, in sub-step 13E, a dipole sub-layer 531 is formed on the structure at each of the first, second and third p-type regions p01, p02, p03, and the first, second and third n-type regions n01, n02, n03 as shown in FIG. 9 using CVD, ALD, or other suitable deposition techniques. In some embodiments, the dipole sub-layer 531 may also be formed on the inner spacers 44 (see FIG. 2) of the patterned structure 40 at each of the first, second and third p-type regions p01, p02, p03, and the first, second and third n-type regions n01, n02, n03. Suitable materials for forming the dipole sub-layer 531 are similar to those for forming the dipole layer 530, and thus details of the possible materials for the dipole sub-layer 531 are omitted for the sake of brevity. In some embodiments, the dipole sub-layer 531 has a thickness ranging from about 0.5 Å to about 25 Å.

Referring the examples illustrated in FIG. 10, in sub-step 13F, at each of the first, second and third p-type regions p01, p02, p03, and the first, second and third n-type regions n01, n02, n03, the capping layer 54 is formed on the dipole sub-layer 531 using CVD, ALD, or other suitable deposition techniques. In some embodiments, the capping layer 54 has a thickness ranging from about 5 Å to about 50 Å.

Referring the examples illustrated in FIGS. 10 and 11, in sub-step 13G, the capping layer 54 and the dipole sub-layer 531 at each of the first, second and third p-type regions p01, p02, p03 are removed, while the capping layer 54 and the dipole sub-layer 531 at each of the first, second and third n-type regions n01, n02, n03 are retained. In some embodiments, sub-step 13G includes (i) forming a photoresist layer and/or a hard mask layer (not shown) on the capping layer 54 at each of the regions p01, p02, p03, n01, n02, n03, using, for example, but not limited to, spin coating, (ii) patterning the photoresist layer and/or the hard mask layer to expose the capping layer 54 at each of the regions p01, p02, p03 using, for example, but not limited to, exposure and developing processes, (iii) sequentially removing the capping layer 54 and the dipole sub-layer 531 at each of the regions p01, p02, p03 using, for example, but not limited to, a wet etching process and/or a dry etching process, and (iv) removing the patterned photoresist layer and/or the patterned hard mask layer using, for example, but not limited to, a stripping process and/or an etching process. In some embodiments, the wet etching process applied for removal of the capping layer 54 and the dipole layer 530 may include use of one or more wet etchant solutions which have a higher etching selectivity (or higher etching rate) over the capping layer 54 and the dipole sub-layer 531 than the interfacial layer 51 and/or the inner spacers 44 (see FIG. 2) so that the interfacial layer 51 and/or the inner spacers 44 are substantially not removed. In some embodiments, the wet etchant solution(s) may be similar to the wet etchant solution used in sub-step 13B but parameter(s) of the etching process (e.g., concentration(s) of the etchant(s), flow rate(s) of etchant(s), concentration ratio of etchant(s), process pressure, process temperature, substrate temperature, etchant temperature, and so on) is tunable to achieve removal of the capping layer 54 and the dipole sub-layer 531 at each of the regions p01, p02, p03. Other chemical solution(s) suitable for removing the dipole sub-layer 531 and the capping layer 54 are within the contemplated scope of the present disclosure.

In the case that the dipole layer 530 is less likely to decompose so as to release the first dipole elements from a side of the dipole layer 530 opposite to the interfacial layer 51, deposition of the capping layer 54 (i.e., sub-step 13F) and removal of the capping layer 54 described in sub-step 13G can be omitted. In this case, the photoresist layer and/or the hard mask layer (not shown) is formed on the dipole sub-layer 531 at each of the regions p01, p02, p03, n01, n02, n03, and the photoresist layer and/or the hard mask layer is patterned to expose the dipole sub-layer 531 at each of the regions p01, p02, p03.

After sub-step 13G, as shown in FIG. 11, at each of the first, second and third n-type regions n01, n02, n03, the dipole layer 530 includes one sub-layer (i.e., the dipole sub-layer 531), and the capping layer 54 is formed on the dipole layer 530. In addition, the dipole layer 530 and the capping layer 54 are not formed at the first, second and third p-type regions p01, p02, p03. In some other embodiments, the dipole layer 530 at each of the regions p01, p02, p03, n01, n02, n03 may include two or more sub-layers. The number of the dipole sub-layer (i.e., a thickness of the dipole layer 530) can be varied according to desired amounts of the first dipole elements to be diffused into the corresponding interfacial layer 51, and according to a space available for film deposition between two adjacent ones of the channel layers 41 in the corresponding patterned structure 40 (see FIGS. 2 and 3).

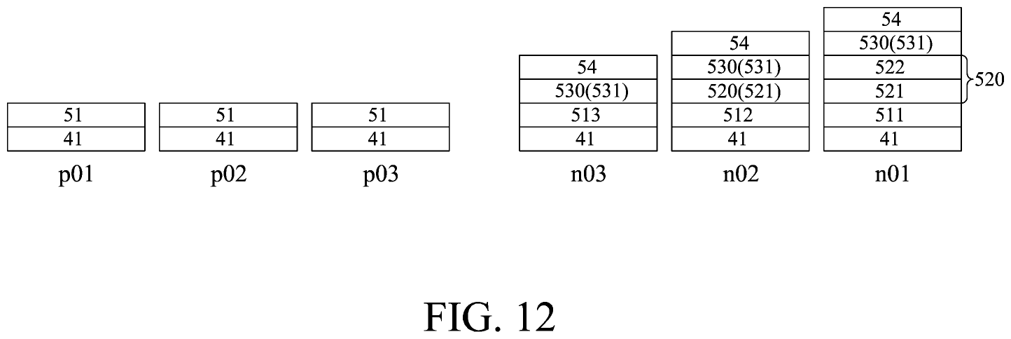

Referring to FIG. 1 and the example illustrated in FIG. 12, the method 100 proceeds to step 134, where a thermal annealing process is performed to permit the first dipole elements in the dipole layer 530 to diffuse (be introduced) into the interfacial layer 51 at each of the first, second and third n-type regions n01, n02, n03, such that doped interfacial layers 511, 512, 513 including the first dipole elements are respectively formed at the regions n01, n02, n03. The first dipole elements in the doped interfacial layer 513 at the third n-type region n03 have an atomic concentration greater than that in the doped interfacial layer 512 at the second n-type region n02, and the first dipole elements in the doped interfacial layer 512 at the second n-type region n02 have an atomic concentration greater than that in the doped interfacial layer 511 at the first n-type region n01. In some embodiments, the atomic concentration of the first dipole elements in the doped interfacial layer 511, 512, 513 at each of the regions n01, n02, n03 ranges from 0.5% to 25%. In some other embodiments, the first dipole elements are introduced into the interfacial layer 51 on at least one of the patterned structures 40 at the regions p01, p02, p03, n01, n02, n03. In some embodiments, the thermal annealing process may be performed at a temperature ranging from about 550° C. to about 750° C. for a time period ranging from about 0.1 seconds to about 60 seconds. In some embodiments, the thermal annealing process includes a rapid thermal annealing (RTA) process, a furnace annealing process, a laser spike annealing process (LSA), or combinations thereof. Other suitable thermal annealing process for facilitating diffusion of the first dipole elements are within the contemplated scope of the present disclosure.

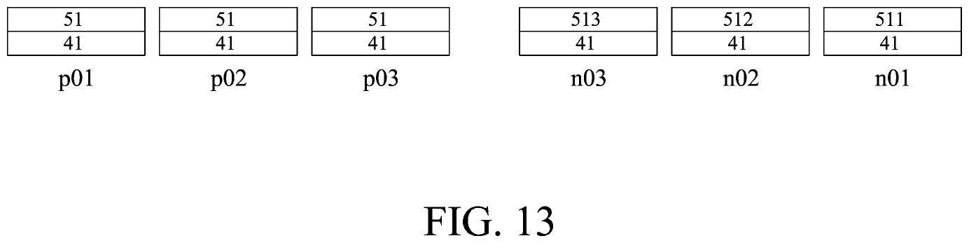

Referring to FIG. 1 and the examples illustrated in FIGS. 12 and 13, the method 100 proceeds to step 135, where the capping layer 54 and the dipole layer 530 are removed from the structure at each of the first, second and third n-type regions n01, n02, n03 as shown in FIG. 12, and the diffusion barrier layer 520 is removed from the structure at each of the first and second n-type regions n01, n02 as shown in FIG. 12, using, for example, but not limited to, a wet etching process or a dry etching process. In some embodiments, the wet etching process applied for removal of the capping layer 54, the dipole layer 530 and the diffusion barrier layer 520 may include use of one or more wet etchant solutions which have a higher etching selectivity (or higher etching rate) over the capping layer 54, the dipole layer 530 and the diffusion barrier layer 520 than the interfacial layer 51 or the doped interfacial layer 511, 512, 513 at each of the regions p01, p02, p03, n01, n02, n03 so that the interfacial layer 51 or the doped interfacial layer 511, 512, 513 at each of the regions p01, p02, p03, n01, n02, n03 is substantially not removed. In some embodiments, the wet etchant solution(s) may be similar to the wet etchant solution used in sub-step 13B but parameter(s) of the etching process (e.g., concentration(s) of the etchant(s), flow rate(s) of etchant(s), concentration ratio of etchant(s), process pressure, process temperature, substrate temperature, etchant temperature, and so on) is tunable to achieve removal of the capping layer 54, the dipole layer 530 and the diffusion barrier layer 520. Other chemical solutions suitable for removing the capping layer 54, the dipole layer 530 and the diffusion barrier layer 520 are within the contemplated scope of the present disclosure.

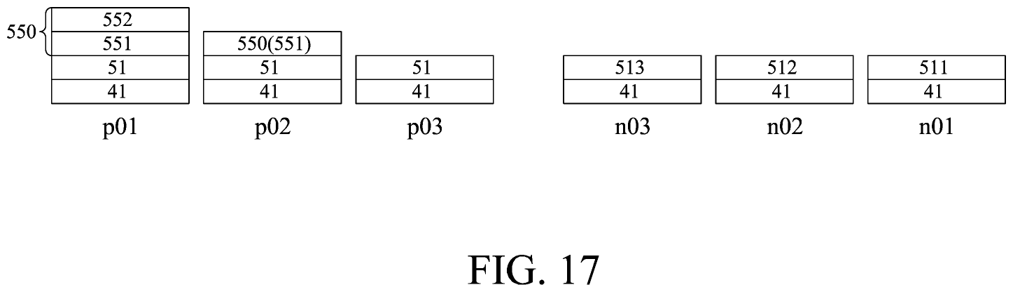

Referring to FIG. 1 and the example illustrated in FIG. 17, the method 100 proceeds to step 141, where a diffusion barrier layer 550 is formed on the interfacial layer 51 on the patterned structure 40 at each of the first and second p-type regions p01, p02, and a thickness of the diffusion barrier layer 550 at the first p-type region p01 is greater than that of the diffusion barrier layer 550 at the second p-type region p02. With the diffusion barrier layer 550 having a predetermined thickness, amounts of second dipole elements (described below) diffusing into the interfacial layer 51 at each of first and second p-type regions p01, p02 can be controlled. The materials, range of thickness, and configurations for the diffusion barrier layer 550 are similar to those for the diffusion barrier layer 520, and thus details thereof are omitted for the sake of brevity.

In some embodiments, step 141 includes sub-steps 14A to 14D.

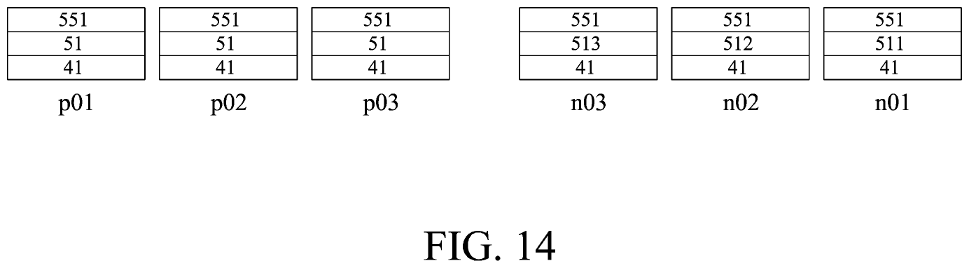

Referring the example illustrated in FIG. 14, in sub-step 14A, a diffusion sub-layer 551 is formed on the structure at each of the first, second and third p-type regions p01, p02, p03, and the first, second and third n-type regions n01, n02, n03 as shown in FIG. 13, using CVD, ALD, or other suitable deposition techniques. In some embodiments, the diffusion sub-layer 551 may also be formed on the inner spacers 44 (see FIG. 2) of the patterned structure 40 at each of the regions p01, p02, p03, n01, n02, n03. The materials, range of thickness for the diffusion sub-layer 551 are similar to those for the diffusion sub-layer 521, and thus details thereof are omitted for the sake of brevity.

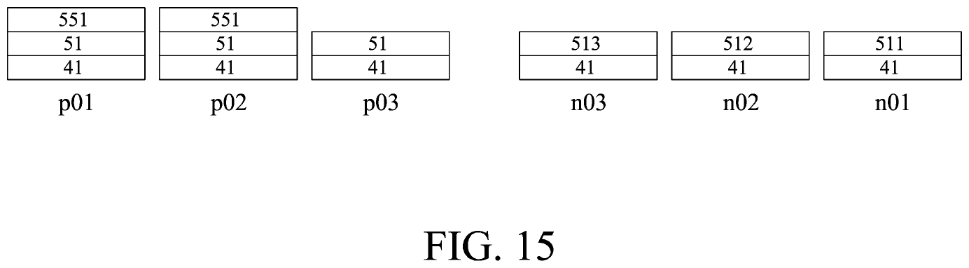

Referring the example illustrated in FIGS. 14 and 15, in sub-step 14B, the diffusion sub-layer 551 at each of the third p-type region p03, and the first, second and third n-type regions n01, n02, n03 is removed, while the diffusion sub-layer 551 at each of the first and second p-type regions p01, p02 is retained. In some embodiments, sub-step 14B includes (i) forming a photoresist layer and/or a hard mask layer (not shown) on the diffusion sub-layer 521 at each of the first, second and third p-type regions p01, p02, p03, and the first, second and third n-type regions n01, n02, n03 as shown in FIG. 14, using, for example, but not limited to, spin coating, (ii) patterning the photoresist layer and/or the hard mask layer to expose the diffusion sub-layer 551 at each of the regions p03, n01, n02, n03 using, for example, but not limited to, exposure and developing processes, (iii) removing the diffusion sub-layer 551 at each of the regions p03, n01, n02, n03 using, for example, but not limited to, a wet etching process and/or a dry etching process, and (iv) removing the patterned photoresist layer and/or the patterned hard mask layer using, for example, but not limited to, a stripping process and/or an etching process. In some embodiments, the wet etchant solution and the etching condition used in the wet etching process applied for removal of the diffusion sub-layer 551 may be similar to the wet etchant solution used in sub-step 13B, and thus details thereof are omitted for the sake of brevity.

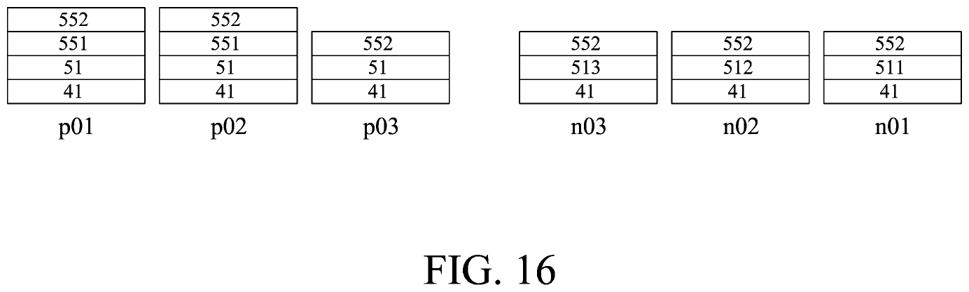

Referring the example illustrated in FIG. 16, in sub-step 14C, an additional diffusion sub-layer 552 is formed on the structure at each of the first, second and third p-type regions p01, p02, p03, and the first, second and third n-type regions n01, n02, n03 as shown in FIG. 15 using CVD, ALD, or other suitable deposition techniques. In some embodiments, the additional diffusion sub-layer 552 may also be formed on the inner spacers 44 (see FIG. 2) of the patterned structures 40 at the regions p03, n01, n02, n03. The materials, range of thickness, and configurations for the additional diffusion sub-layer 552 are similar to those for the diffusion sub-layer 551, and thus details thereof are omitted for the sake of brevity.

Referring the example illustrated in FIGS. 16 and 17, in sub-step 14D, the additional diffusion sub-layer 552 at each of the second and third p-type regions p02, p03, and the first, second and third n-type regions n01, n02, n03 is removed, while the additional diffusion sub-layer 552 at the first p-type region p01 is retained. In some embodiments, sub-step 14D includes (i) forming a photoresist layer and/or a hard mask layer (not shown) on the additional diffusion sub-layer 552 at each of the first, second and third p-type regions p01, p02, p03, and the first, second and third n-type regions n01, n02, n03, using, for example, but not limited to, spin coating, (ii) patterning the photoresist layer and/or the hard mask layer to expose the additional diffusion sub-layer 552 at each of the regions p02, p03, n01, n02, n03 using, for example, but not limited to, exposure and developing processes, (iii) removing the additional diffusion sub-layer 552 at each of the regions p02, p03, n01, n02, n03 using, for example, but not limited to, a wet etching process and/or a dry etching process, and (iv) removing the patterned photoresist layer and/or the patterned hard mask layer using, for example, but not limited to, a stripping process and/or an etching process. In some embodiments, the wet etchant solution and the etching condition used in the wet etching process applied for removal of the additional diffusion sub-layer 552 may be similar to those in sub-step 13D, and thus details thereof are omitted for the sake of brevity.

After sub-step 14D, as shown in FIG. 17, the diffusion barrier layer 550 at the first p-type region p01 includes two sub-layers (i.e., the diffusion sub-layer 551 and the additional diffusion sub-layer 552), and the diffusion barrier layer 550 at the second p-type region p02 includes one sub-layer (i.e., the diffusion sub-layer 551). In addition, the diffusion barrier layer 550 is not formed at the first, second and third n-type regions n01, n02, n03, and the third p-type region p03. In some other embodiments, the number of the sub-layers (i.e., the thickness of the diffusion barrier layer 550) on the interfacial layer 51 at each of the regions p01, p02, p03, n01, n02, n03 can be varied according to desired amounts of the second dipole elements (to be described hereinafter) to be diffused into the corresponding interfacial layer 51, and according to a space available for film deposition between two adjacent ones of the channel layers 41 in the corresponding patterned structure 40 (see FIGS. 2 and 3).

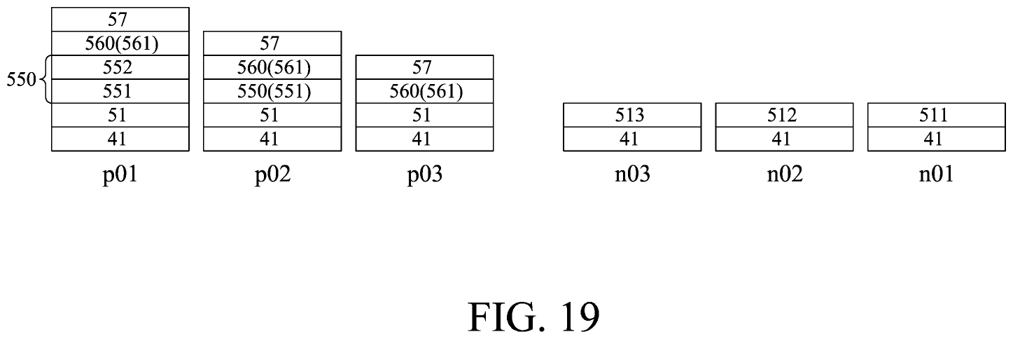

Referring to FIG. 1 and the example illustrated in FIG. 19, the method 100 proceeds to step 142, where a dipole layer 560 is formed on the structure at each of the first, second and third p-type regions p01, p02, p03 as shown in FIG. 17. The dipole layer 560 serves as a source that provides the second dipole elements to be diffused into the interfacial layer 51, and thus the dipole layer 560 includes the second dipole elements. In some embodiments, the second dipole elements includes zinc (Zn), gallium (Ga), lanthanum (La), magnesium (Mg), or combinations thereof. In some embodiments, the second dipole elements in the dipole layer 560 may be the same or different from the first dipole elements in the dipole layer 530. For example, when gallium is selected as the second dipole elements, the dipole layer 560 may be made of gallium oxide, gallium nitride, gallium oxynitride, but is not limited thereto. The materials, range of thickness, and configurations for the dipole layer 560 are similar to those for the dipole layer 530, and thus details thereof are omitted for the sake of brevity.

Referring to FIG. 1 and the example illustrated in FIG. 19, the method 100 proceeds to steps 143, where at each of the first, second and third p-type regions p01, p02, p03, a capping layer 57 is formed on the dipole layer 560 opposite to the interfacial layer 51. The capping layer 57 is provided to stabilize chemical properties of the dipole layer 560 at each of the regions p01, p02, p03 during a thermal annealing process to be performed subsequently. The materials, range of thickness, and configurations for the capping layer 57 are similar to those for the capping layer 54, and thus details thereof are omitted for the sake of brevity.

In some embodiments, formation of the dipole layer 560 and the capping layer 57 (i.e., steps 142 and 143) may include sub-steps 14E to 14G.

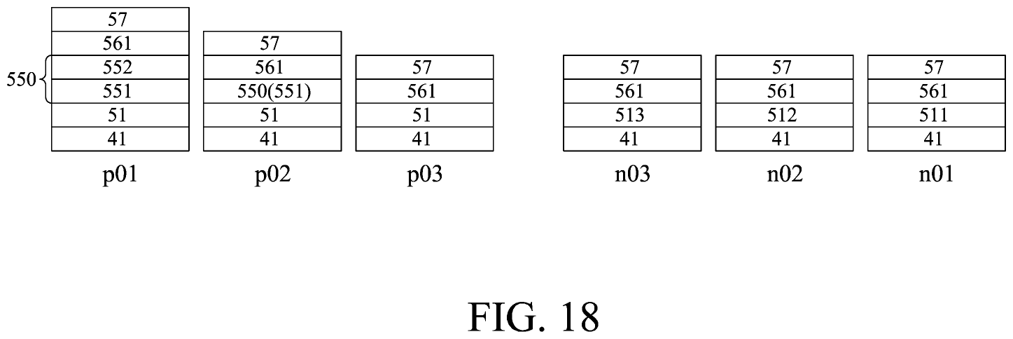

Referring the examples illustrated in FIG. 18, in sub-step 14E, a dipole sub-layer 561 is formed on the structure at each of the first, second and third p-type regions p01, p02, p03, and the first, second and third n-type regions n01, n02, n03 as shown in FIG. 17 using CVD, ALD, or other suitable deposition techniques. In some embodiments, the dipole sub-layer 561 may also be formed on the inner spacers 44 (see FIG. 2) of the patterned structure 40 at each of the regions p01, p02, p03, n01, n02, n03. The materials, range of thickness, and configurations for the dipole sub-layer 561 are similar to those for the dipole sub-layer 531, and thus details thereof are omitted for the sake of brevity.

Referring the examples illustrated in FIG. 18, in sub-step 14F, at each of the first, second and third p-type regions p01, p02, p03, and the first, second and third n-type regions n01, n02, n03, the capping layer 57 is formed on the dipole sub-layer 561 using CVD, ALD, or other suitable deposition techniques. In some embodiments, the capping layer 57 has a thickness ranging from about 5 Å to about 50 Å.

Referring the examples illustrated in FIGS. 18 and 19, in sub-step 14G, the capping layer 57 and the dipole sub-layer 561 at each of the first, second and third n-type regions n01, n02, n03 are removed, while the capping layer 57 and the dipole sub-layer 561 at each of the first, second and third p-type regions p01, p02, p03 are retained. In some embodiments, sub-step 14G includes (i) forming a photoresist layer and/or a hard mask layer (not shown) on the capping layer 54 at each of the regions p01, p02, p03, n01, n02, n03, using, for example, but not limited to, spin coating, (ii) patterning the photoresist layer and/or the hard mask layer to expose the capping layer 57 at each of the regions n01, n02, n03 using, for example, but not limited to, exposure and developing processes, (iii) sequentially removing the capping layer 57 and the dipole sub-layer 561 at each of the regions n01, n02, n03 using, for example, but not limited to, a wet etching process and/or a dry etching process, and (iv) removing the patterned photoresist layer and/or the patterned hard mask layer using, for example, but not limited to, a stripping process and/or an etching process. In some embodiments, the wet etchant solution and the etching condition used in the wet etching process applied for removal of the capping layer 57 and the dipole sub-layer 561 may be similar to those in sub-step 13G, and thus details thereof are omitted for the sake of brevity.

In the case that the dipole layer 560 is less likely to decompose so as to release the second dipole elements from a side of the dipole layer 560 opposite to the interfacial layer 51, deposition of the capping layer 57 (i.e., sub-step 14F) and removal of the capping layer 57 described in sub-step 14G can be omitted. In this case, the photoresist layer and/or the hard mask layer (not shown) is formed on the dipole sub-layer 561 at each of the regions p01, p02, p03, n01, n02, n03, and the photoresist layer and/or the hard mask layer is patterned to expose the dipole sub-layer 561 at each of the regions n01, n02, n03.

After sub-step 14G, as shown in FIG. 19, at the first, second and third p-type regions p01, p02, p03, the dipole layer 560 includes one sub-layer (i.e., the dipole sub-layer 561), and the capping layer 57 is formed on the dipole layer 560. In addition, the dipole layer 560 and the capping layer 57 are not formed at the first, second and third n-type regions n01, n02, n03. In some other embodiments, the dipole layer 560 at each of the regions p01, p02, p03, n01, n02, n03 may include two or more sub-layers. The number of the dipole sub-layer (i.e., a thickness of the dipole layer 560) can be varied according to desired amounts of the second dipole elements to be diffused into the corresponding interfacial layer 51, and according to a space available for film deposition between two adjacent ones of the channel layers 41 in the corresponding patterned structure 40 (see FIGS. 2 and 3).

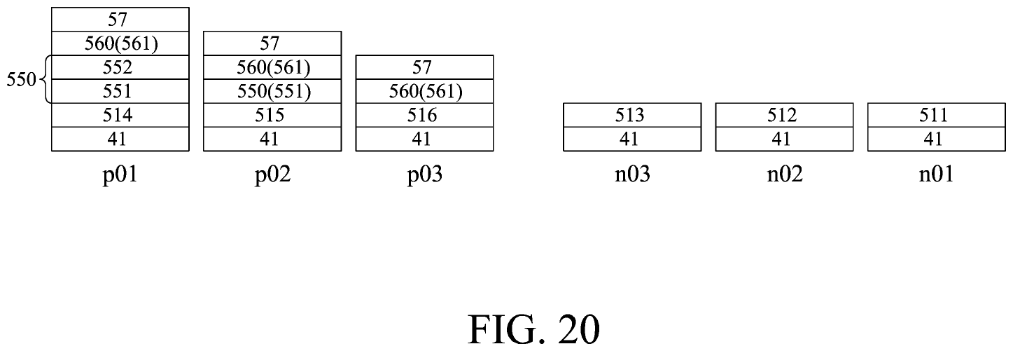

Referring to FIG. 1 and the example illustrated in FIG. 20, the method 100 proceeds to step 144, where a thermal annealing process is performed to permit the second dipole elements in the dipole layer 560 to diffuse (be introduced) into the interfacial layer 51 at each of the first, second and third p-type regions p01, p02, p03, such that doped interfacial layers 514, 515, 516 including the second dipole elements are respectively formed at the regions p01, p02, p03. The second dipole elements in the doped interfacial layer 516 at the third p-type region p03 have an atomic concentration greater than that in the doped interfacial layer 515 at the second p-type region p02, and the second dipole elements in the doped interfacial layer 515 at the second p-type region p02 have an atomic concentration greater than that in the doped interfacial layer 514 at the first p-type region p01. In some embodiments, the atomic concentration of the second dipole elements in the doped interfacial layer 514, 515, 515 at each of the regions p01, p02, p03 ranges from 0.5% to 25%. In some other embodiments, the second dipole elements are introduced into the interfacial layer 51 on at least one of the patterned structures 40 at the regions p01, p02, p03, n01, n02, n03. Since the possible processes and the parameters for the thermal annealing process in step 144 are similar to those described in step 134, the details thereof are omitted for the sake of brevity.

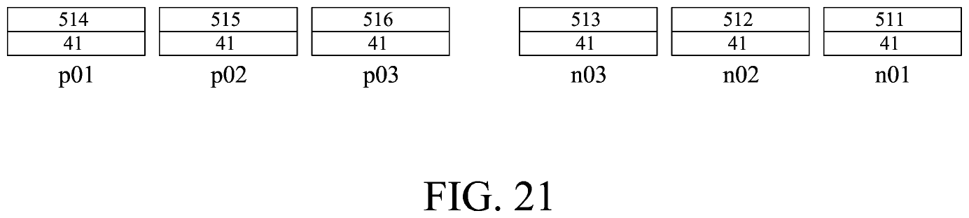

Referring to FIG. 1 and the examples illustrated in FIGS. 20 and 21, the method 100 proceeds to step 145, where the capping layer 57 and the dipole layer 560 at each of the first, second and third p-type regions p01, p02, p03 as shown in FIG. 20 are removed, and the diffusion barrier layer 550 at each of the first and second p-type regions p02, p03 as shown in FIG. 20 is removed, using, for example, but not limited to, a wet etching process and/or a dry etching process. In some embodiments, the wet etchant solution and the etching condition used in the wet etching process applied for removal of the capping layer 57, the dipole layer 560 and the diffusion barrier layer 550 may be similar to those described in step 135, and thus details thereof are omitted for the sake of brevity.

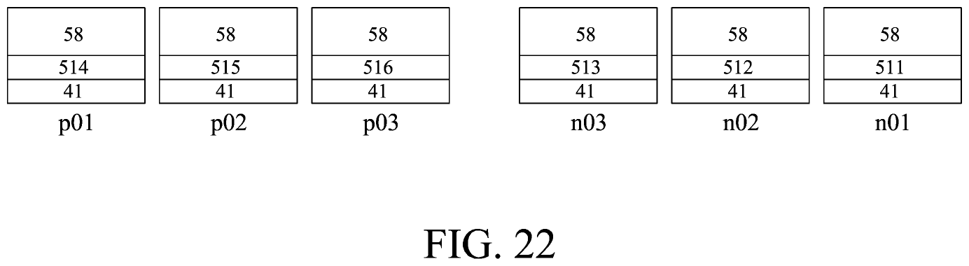

Referring to FIG. 1 and the example illustrated in FIG. 22, the method 100 proceeds to step 150, where a gate dielectric layer 58 is formed on the doped interfacial layers 511, 512, 513, 514, 515, 516 respectively at the first, second and third n-type regions n01, n02, n03 and the first, second and third p-type regions p01, p02, p03 using CVD, ALD, or other suitable deposition techniques. In some embodiments, the gate dielectric layer 58 may also be formed on the inner spacers 44 (see FIG. 2) of the patterned structure 40 at each of the regions p01, p02, p03, n01, n02, n03. In some embodiments, the gate dielectric layer 58 includes silicon oxide, silicon nitride, silicon oxynitride, high dielectric constant (k) materials, other suitable materials, or combinations thereof. For example, the gate dielectric layer 58 may be made of hafnium oxide (HfOₓ), zirconia oxide (ZrOₓ), hafnium zirconia oxide (ZrOₓ), but is not limited thereto. Other suitable materials for forming the gate dielectric layer 58 are within the contemplated scope of the present disclosure. In some embodiments, the gate dielectric layer 58 has a thickness ranging from about 8 Å to about 20 Å.

Referring to FIG. 1 and the example illustrated in FIG. 23, the method 100 proceeds to step 160, where a gate electrode 59 is formed on the gate dielectric layer 58 at each of the first, second and third n-type regions n01, n02, n03 and the first, second and third p-type regions p01, p02, p03, such that the semiconductor devices 30 formed at the regions n01, n02, n03, p01, p02, p03 are obtained. FIG. 24 is a schematic sectional view of one of the semiconductor devices 30 in accordance with some embodiments. FIG. 25 is a schematic sectional view of the one of the semiconductor devices 30 taken long line D-D′ of FIG. 24. FIG. 23 is a schematic view illustrating regions EE of the semiconductor devices 30 (each being shown in FIG. 24) or regions FF of the semiconductor devices 30 (each being shown in FIG. 25). Please note that although the doped interfacial layers shown in FIGS. 24 and 25 and obtained in step 160 may be one of the doped interfacial layer 511, 512, 513, 514, 515, 516 as shown in FIG. 23, the interfacial layers as shown in FIG. 24 are denoted by numeral 51 for simplified illustration. In some embodiments, the gate electrode 59 may be configured as a single-layer structure or a multi-layered structure. In some embodiments, the gate electrode 59 may include at least one work function metal layer (not shown), a glue layer (not shown), and a metal filling layer (not shown). In some embodiments, the at least one work function metal layer is provided for adjusting threshold voltage of the semiconductor devices 30. In some embodiments, the at least one work function metal layer may have a mid-gap work function, that is, the at least one work function metal layer has a Fermi-energy level that is close to half of energy levels of a conduction band edge and a valance band edge of the channel layer 41. In some embodiments, the at least one work function metal layer may be made of titanium nitride (TiN), tantalum nitride (TaN), titanium aluminide (TiAl), titanium aluminum carbide (TiAlC), titanium aluminum carbon nitride (TiAlCN), or combinations thereof. Other suitable materials for forming the work function metal layer are within the contemplated scope of the present disclosure. In some embodiments, the work function metal layer has a thickness ranging from about 10 Å to about 50 Å. In some embodiments, the glue layer is optional, but is often used to provide a desired adhesion to the metal filling layer to be formed thereon. In some embodiments, the glue layer includes nitride-based materials, such as titanium nitride (TiN), tantalum nitride (TaN), tungsten nitride (WN), or combinations thereof. Other suitable materials for forming the glue layer are within the contemplated scope of the present disclosure. In some embodiments, the glue layer has a thickness ranging from about 10 Å to about 100 Å. In some embodiments, the metal filling layer is provided for reducing electrical conductivity of the gate electrode 59, and includes a low conductivity metal, such as tungsten (W), cobalt (Co), ruthenium (Ru), iridium (Ir), alloy thereof, or combinations thereof. Other suitable materials for forming the metal filling layer are within the contemplated scope of the present disclosure. In some embodiments, the metal filling layer has a thickness ranging from about 30 Å to about 1000 Å. In some embodiments, the gate electrodes 59 of the semiconductor devices 30 have the same thickness or the same configuration. In some embodiments, step 160 includes (i) sequentially depositing materials for forming the work function metal layer(s), the glue layer, and the metal filling layer using CVD, ALD or other suitable processes to fill the cavities 48 of the patterned structures obtained after step 150 (see FIG. 2), and (ii) performing a planarization process, for example, but not limited to, CMP or other suitable processes, thereby obtaining the work function metal layer(s), the glue layer, and the metal filling layer.

Referring to FIG. 23, since the semiconductor devices 30 (one of which is shown in FIGS. 24 and 25) at the first, second and third n-type regions n01, n02, n03 are n-FETs, threshold voltage (Vt) values for the semiconductor devices 30 at the regions n01, n02, n03 are positive. In the case that the first dipole elements are La (or Mg), according to atomic concentrations of the first dipole elements in the doped interfacial layer 511, 512, 513 at each of the regions n01, n02, n03 (i.e., the atomic concentrations of the first dipole elements in the doped interfacial layer: n03>n02>n01), the semiconductor device 30 at the region n03 would have a lower Vt value than that of the semiconductor device 30 at the region n02, and the semiconductor device 30 at the region n02 would have a lower Vt value than that of the semiconductor device 30 at the region n01 (i.e., the Vt value: n03<n02<n01). In the case that the first dipole elements in the doped interfacial layer 511, 512, 513 at each of the regions n01, n02, n03 are Ga (or Zn), the semiconductor device 30 at the region n03 would have a higher Vt value than that of the semiconductor device 30 at the region n02, and the semiconductor device 30 at the region n02 would have a higher Vt value than that of the semiconductor device 30 at the region n01 (i.e., the Vt value: n03>n02>n01).

Since the semiconductor devices 30 at the first, second and third n-type regions p01, p02, p03 are p-FETs, Vt values for the semiconductor devices 30 at the regions p01, p02, p03 are negative. In the case that the second dipole elements are Ga (or Zn), according to atomic concentrations of the second dipole elements in the doped interfacial layer 514, 514, 516 at each of the regions p01, p02, p03 (i.e., the atomic concentrations of the second dipole elements in the doped interfacial layer: p03>p02>p01), the semiconductor device 30 at the region p01 would have a lower Vt value than that of the semiconductor device 30 at the region p02, and the semiconductor device 30 at the region p02 would have a lower Vt value than that of the semiconductor device 30 at the region p03 (i.e., the Vt value: p01<p02<p03). In the case that the second dipole elements in the doped interfacial layer 514, 515, 516 at each of the regions p01, p02, p03 is La (or Mg), the semiconductor device 30 at the region p01 would have a higher Vt value than that of the semiconductor device 30 at the region p02, and the semiconductor device 30 at the region p02 would have a higher Vt value than that of the semiconductor device 30 at the region p03 (i.e., the Vt value: p01>p02>p03).

It can be concluded that for the n-FETs and p-FETs, as the atomic concentration of La (or Mg) in the doped interfacial layer increases, the Vt value will become more negative, and vice versa. As the atomic concentration of Ga (or Zn) in the doped interfacial layer increases, the Vt value will become more positive, and vice versa.

In some embodiments, some steps in the method 100 may be modified, replaced, or eliminated without departure from the spirit and scope of the present disclosure. For example, introduction of the first dipole elements (i.e., steps 131 to 135) and introduction of the second dipole elements (i.e., steps 141 to 145) can be swapped. In some alternative embodiments, other suitable methods may also be applied for forming the semiconductor structure 20.

In the method 100, the first dipole elements are introduced into the interfacial layers 51 before formation of the gate dielectric layer 58 (i.e., an N dipole-first process) and the second dipole elements are introduced into the interfacial layers 51 before formation of the gate dielectric layer 58 (i.e., a P dipole-first process). In some alternative embodiments, the first dipole elements or the second dipole elements may be introduced into the interfacial layers 51 after formation of a gate dielectric layer (i.e., an N dipole-last process or a P dipole-last process). In the following description, the N dipole-first process and the P dipole-last process are used for manufacturing a semiconductor structure including semiconductor devices with different threshold voltage values, although in some alternative embodiments, the P dipole-first process and the N dipole-last process may be used for manufacturing a semiconductor structure including semiconductor devices with different threshold voltage values.

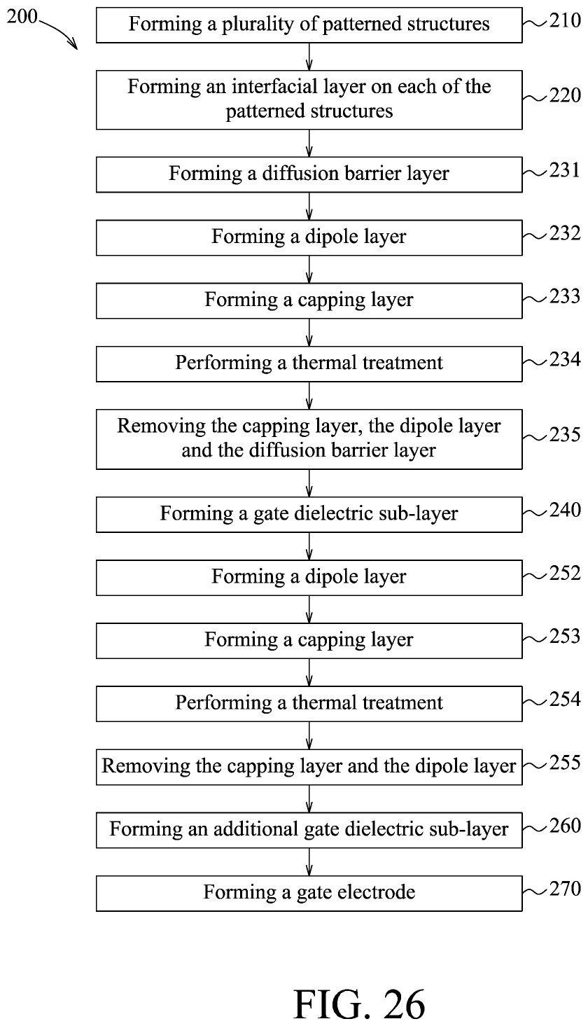

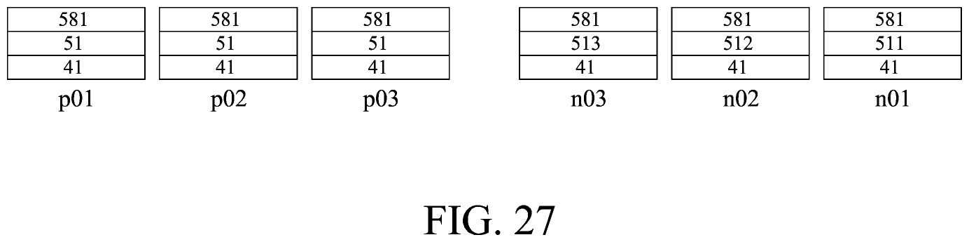

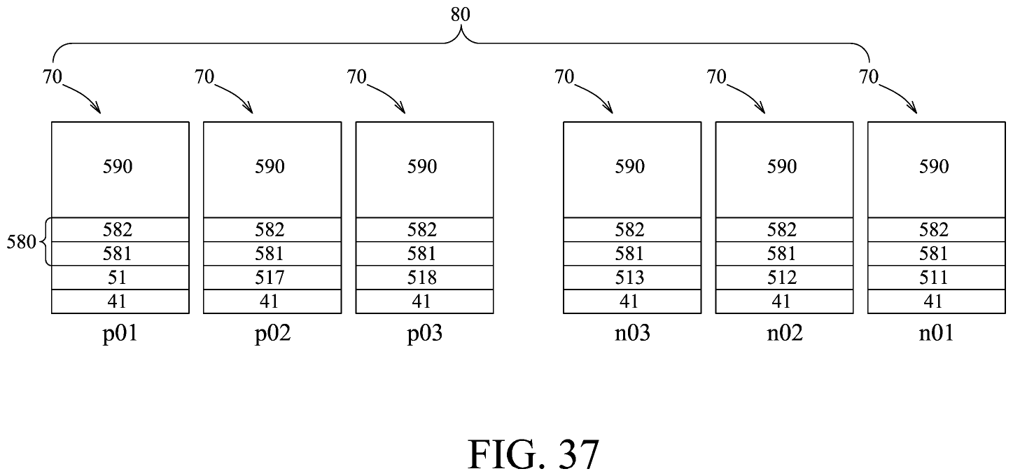

FIG. 26 is a flow diagram illustrating a method 200 for manufacturing a semiconductor structure (for example, a semiconductor structure 80 shown in FIG. 37) in accordance with some embodiments. FIGS. 27 to 37 illustrate schematic views of the intermediate stages of the method 200 in accordance with some embodiments. The method includes steps 210 to 270, where steps 210 to 235 are similar to steps 110 to 135 described above with reference to FIGS. 4 to 13, and thus details thereof are omitted for the sake of brevity.

Referring to FIG. 26 and the example illustrated in FIG. 27, the method 200 proceeds to step 240, where a gate dielectric sub-layer 581 is formed on the structure at each of the first, second and third p-type regions p01, p02, p03 and the first, second and third n-type regions n01, n02, n03 as shown in FIG. 13. In some embodiments, the gate dielectric sub-layer 581 may also be formed on the inner spacers 44 (see FIG. 2) of the patterned structure 40 at each of the regions p01, p02, p03, n01, n02, n03. Materials suitable for forming the gate dielectric sub-layer 581 are similar to those for forming the gate dielectric layer 58, and thus details thereof are omitted for the sake of brevity. In some embodiments, in consideration of a remaining space available for subsequent film deposition between two adjacent ones of the channel layers 41 in the corresponding patterned structure 40 (see FIGS. 2 and 3), the gate dielectric sub-layer 581 has a thickness less than that of the gate dielectric layer 58.

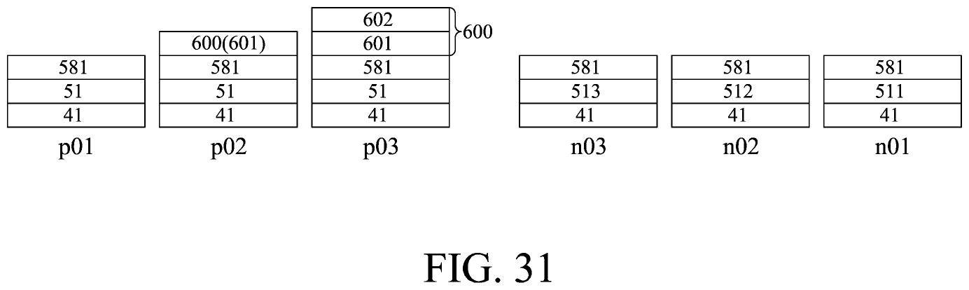

Referring to FIG. 26 and the example illustrated in FIG. 31, the method 100 proceeds to step 252, where a dipole layer 600 is formed on the gate dielectric sub-layer 581 at each of the second and third p-type regions p02, p03, and a thickness of the dipole layer 600 at the first p-type region p03 is greater than that of the dipole layer 600 at the second p-type region p02. The dipole layer 600 serves as a source that provides the second dipole elements to be diffused into the interfacial layer 51, and thus the dipole layer 600 includes the second dipole elements as abovementioned. The thickness of the dipole layer 600 aims to control amounts of the second dipole elements diffused into the interfacial layer 51 at each of regions p02, p03. In some embodiments, the second dipole elements in the dipole layer 600 may be the same or different from the first dipole elements in the dipole layer 530 (see abovementioned step 132 and FIG. 11). For example, when zinc is selected as the first dipole elements, the dipole layer 530 may be made of zinc oxide, zinc nitride, zinc oxynitride, but is not limited thereto. The materials, range of thickness, and configurations for the dipole layer 600 are similar to those for the dipole layer 560 (see abovementioned step 142 and FIG. 19), and thus details thereof are omitted for the sake of brevity.

In some embodiments, step 252 includes sub-steps 25A to 25D.

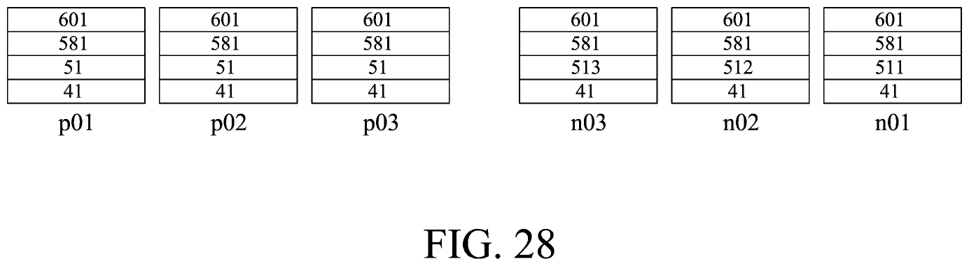

Referring the example illustrated in FIG. 28, in sub-step 25A a dipole sub-layer 601 is formed on the structure at each of the first, second and third p-type regions p01, p02, p03, and the first, second and third n-type regions n01, n02, n03 as shown in FIG. 27 using CVD, ALD, or other suitable deposition techniques. The materials, range of thickness, and configurations for the dipole sub-layer 601 are similar to those for the dipole sub-layer 561 (see abovementioned sub-step 14E and FIG. 18), and thus details thereof are omitted for the sake of brevity.

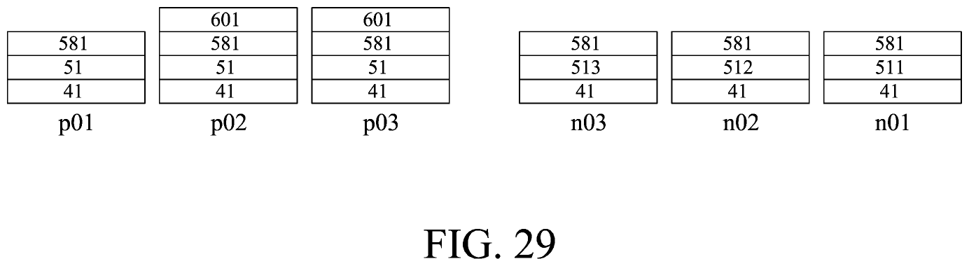

Referring the example illustrated in FIGS. 28 and 29, in sub-step 25B, the dipole sub-layer 601 at each of the first p-type region p01, and the first, second and third n-type regions n01, n02, n03 is removed, while the dipole sub-layer 601 at each of the second and third p-type regions p02, p03 is retained. In some embodiments, sub-step 25B includes (i) forming a photoresist layer and/or a hard mask layer (not shown) on the diffusion sub-layer 521 at each of the first, second and third p-type regions p01, p02, p03, and the first, second and third n-type regions n01, n02, n03 as shown in FIG. 28, using, for example, but not limited to, spin coating, (ii) patterning the photoresist layer and/or the hard mask layer to expose the gate dielectric sub-layer 581 at each of the regions p01, n01, n02, n03 using, for example, but not limited to, exposure and developing processes, (iii) removing the dipole sub-layer 601 at each of the regions p01, n01, n02, n03 using, for example, but not limited to, a wet etching process and/or a dry etching process, and (iv) removing the patterned photoresist layer and/or the patterned hard mask layer using, for example, but not limited to, a stripping process and/or an etching process. In some embodiments, the wet etching process applied for removal of the dipole sub-layer 601 may include use of one or more wet etchant solutions which have a higher etching selectivity (or higher etching rate) over the dipole sub-layer 601 than the gate dielectric sub-layer 581 so that the gate dielectric sub-layer 581 are substantially not removed. In some embodiments, the wet etchant solution(s) may be similar to the wet etchant solution used in sub-step 13G but parameter(s) of the etching process (e.g., concentration(s) of the etchant(s), flow rate(s) of etchant(s), concentration ratio of etchant(s), process pressure, process temperature, substrate temperature, etchant temperature, and so on) is tunable to achieve removal of the dipole sub-layer 601 at each of the regions p01, n01, n02, n03. Other chemical solution(s) suitable for removing the dipole sub-layer 601 are within the contemplated scope of the present disclosure.

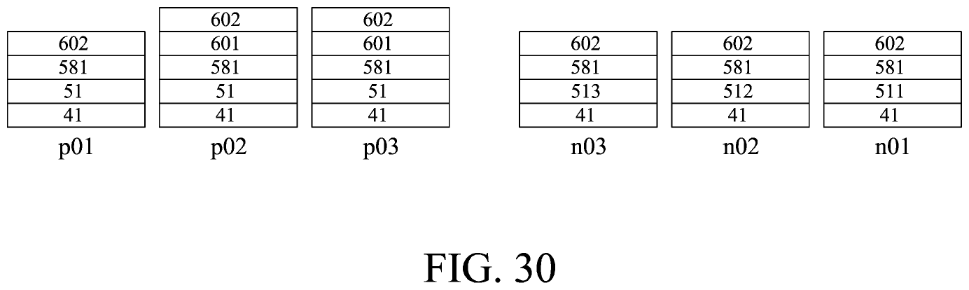

Referring the example illustrated in FIG. 30, in sub-step 25C, an additional dipole sub-layer 602 is formed on the structure at each of the first, second and third p-type regions p01, p02, p03, and the first, second and third n-type regions n01, n02, n03 as shown in FIG. 29 using CVD, ALD, or other suitable deposition techniques. The materials, range of thickness, and configurations for the additional dipole sub-layer 602 are similar to those for the dipole sub-layer 601, and thus details thereof are omitted for the sake of brevity.

Referring the example illustrated in FIGS. 30 and 31, in sub-step 25D, the additional dipole sub-layer 602 at each of the first and second p-type regions p01, p02, and the first, second and third n-type regions n01, n02, n03 is removed, while the additional dipole sub-layer 602 at the third p-type region p03 is retained. In some embodiments, sub-step 25D includes (i) forming a photoresist layer and/or a hard mask layer (not shown) on the additional dipole sub-layer 602 at each of the first, second and third p-type regions p01, p02, p03, and the first, second and third n-type regions n01, n02, n03, using, for example, but not limited to, spin coating, (ii) patterning the photoresist layer and/or the hard mask layer to expose the additional dipole sub-layer 602 at each of the regions p01, p02, n01, n02, n03 using, for example, but not limited to, exposure and developing processes, (iii) removing the additional dipole sub-layer 602 at each of the regions p01, p02, n01, n02, n03 using, for example, but not limited to, a wet etching process and/or a dry etching process, and (iv) removing the patterned photoresist layer and/or the patterned hard mask layer using, for example, but not limited to, a stripping process and/or an etching process. In some embodiments, the wet etching process applied for removal of the additional diffusion sub-layer 522 may include use of a wet etchant solution similar to the wet etchant solution used in sub-step 25B, and thus details thereof are omitted for the sake of brevity. In addition, the wet etching process in sub-step 25D may be a time-controlled etching process so that the etching is stopped after a period of time so as to prevent the dipole sub-layer 601 formed beneath the additional dipole sub-layer 602 at the second p-type region p02 from being removed during sub-step 25D.

After sub-step 25D, as shown in FIG. 31, the dipole layer 600 at the third p-type region p03 includes two sub-layers (i.e., the dipole sub-layer 601 and the additional dipole sub-layer 602), the dipole layer 600 at the second p-type region n01 includes one sub-layer (i.e., the dipole sub-layer 601). In addition, the dipole layer 600 is not formed at the first p-type region p01, and the first, second and third n-type regions n01, n02, n03. In some embodiments, the number of the sub-layers (i.e., the thickness of the dipole layer 600) on the gate dielectric sub-layer 581 at each of the regions p01, p02, p03, n01, n02, n03 can be varied according to desired amounts of the second dipole elements to be diffused into the corresponding interfacial layer 51 or the corresponding doped interfacial layer 511, 512, 513, and according to a space available for film deposition between two adjacent ones of the channel layers 41 in the corresponding patterned structure 40 (see FIGS. 2 and 3).

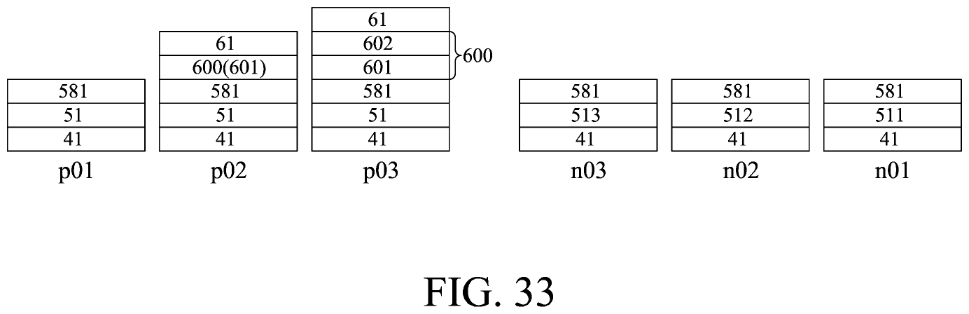

Referring to FIG. 26 and the example illustrated in FIG. 33, the method 200 proceeds to steps 253, where at each of the second and third p-type regions p02, p03, a capping layer 61 is formed on the dipole layer 600 opposite to the gate dielectric sub-layer 581. The capping layer 61 is provided to stabilize chemical properties of the dipole layer 600 at each of the regions p02, p03 during a thermal annealing process to be performed subsequently. The materials, range of thickness, and configurations for the capping layer 61 are similar to those for the capping layer 57, and thus details thereof are omitted for the sake of brevity.

In some embodiments, step 253 includes sub-steps 25E to 25F.

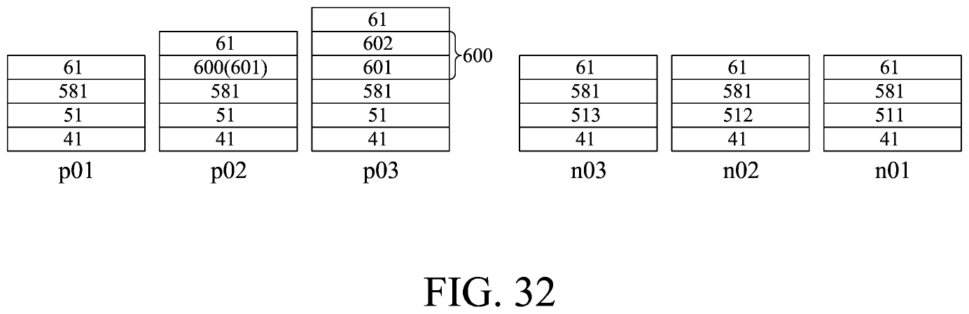

Referring the examples illustrated in FIG. 32, in sub-step 25E, the capping layer 61 is formed on the structure at each of the first, second and third p-type regions p01, p02, p03, and the first, second and third n-type regions n01, n02, n03 using CVD, ALD, or other suitable deposition techniques. In some embodiments, the capping layer 61 has a thickness ranging from about 5 Å to about 50 Å.

Referring the examples illustrated in FIGS. 32 and 33, in sub-step 25F, the capping layer 61 at each of the first p-type region p01, and the first, second and third n-type regions n01, n02, n03 are removed, while the capping layer 61 at each of the second and third p-type regions p02, p03 are retained. In some embodiments, sub-step 25F includes (i) forming a photoresist layer and/or a hard mask layer (not shown) on the capping layer 61 at each of the regions p01, p02, p03, n01, n02, n03, using, for example, but not limited to, spin coating, (ii) patterning the photoresist layer and/or the hard mask layer to expose the capping layer 61 at each of the regions p01, n01, n02, n03 using, for example, but not limited to, exposure and developing processes, (iii) sequentially removing the capping layer 61 at each of the regions p01, n01, n02, n03 using, for example, but not limited to, a wet etching process and/or a dry etching process, and (iv) removing the patterned photoresist layer and/or the patterned hard mask layer using, for example, but not limited to, a stripping process and/or an etching process. In some embodiments, the wet etching process applied for removal of the capping layer 61 may include use of one or more wet etchant solutions which have a higher etching selectivity (or higher etching rate) over the capping layer 61 than the gate dielectric sub-layer 581 so that the gate dielectric sub-layer 581 are substantially not removed. In some embodiments, the wet etchant solution(s) may be similar to the wet etchant solution used in sub-step 13G but parameter(s) of the etching process (e.g., concentration(s) of the etchant(s), flow rate(s) of etchant(s), concentration ratio of etchant(s), process pressure, process temperature, substrate temperature, etchant temperature, and so on) is tunable to achieve removal of the capping layer 61 at each of the regions p01, n01, n02, n03. Other chemical solution(s) suitable for removing the capping layer 61 are within the contemplated scope of the present disclosure.

In the case that the dipole layer 600 is less likely to decompose so as to release the second dipole elements from a side of the dipole layer 600 opposite to the gate dielectric sub-layer 581, formation of the capping layer 61 (i.e., step 253) can be omitted.

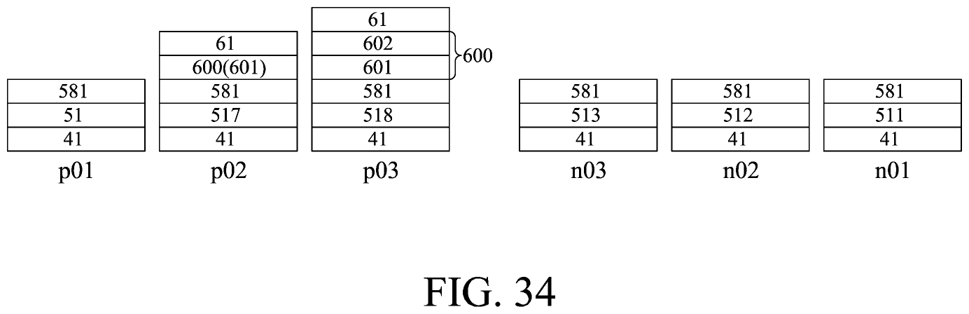

Referring to FIG. 26 and the example illustrated in FIG. 34, the method 200 proceeds to steps 254, where a thermal annealing process is performed to permit the second dipole elements in the dipole layer 600 to diffuse (be introduced) into the interfacial layer 51 at each of the second and third p-type regions p02, p03, such that doped interfacial layers 517, 518 including the second dipole elements are respectively formed at the regions p02, p03. The second dipole elements in the doped interfacial layer 518 at the third p-type region p03 have an atomic concentration greater than that in the doped interfacial layer 517 at the second p-type region p02, and the second dipole elements in the doped interfacial layer 517 at the second p-type region p02 have an atomic concentration greater than that in the interfacial layer 51 at the first p-type region p01. In some embodiments, the atomic concentration of the second dipole elements in the doped interfacial layer 517, 518 at each of the regions p02, p03 ranges from 0.5% to 25%. In some other embodiments, the second dipole elements are introduced into the interfacial layer 51 on at least one of the patterned structures 40 at the regions p01, p02, p03, n01, n02, n03. Since the possible processes and the parameters for the thermal annealing process in step 254 are similar to those described in step 144, the details thereof are omitted for the sake of brevity.

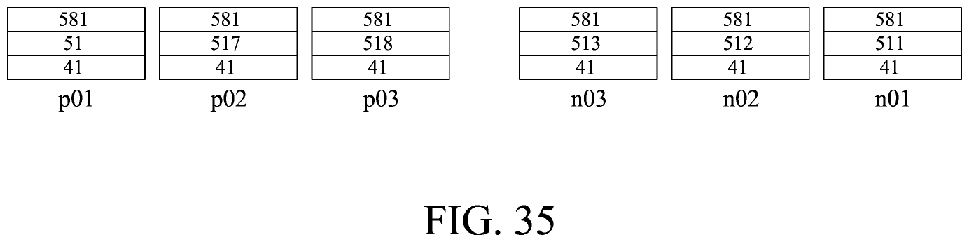

Referring to FIG. 26 and the examples illustrated in FIGS. 34 and 35, the method 200 proceeds to step 255, where the capping layer 61 and the dipole layer 600 at each of the second and third p-type regions p02, p03 as shown in FIG. 34 are removed, using, for example, but not limited to, a wet etching process and/or a dry etching process. In some embodiments, the wet etchant solution and the etching condition used in the wet etching process applied for removal of the capping layer 61 and the dipole layer 600 may be similar to those described in step 145, and thus details thereof are omitted for the sake of brevity.

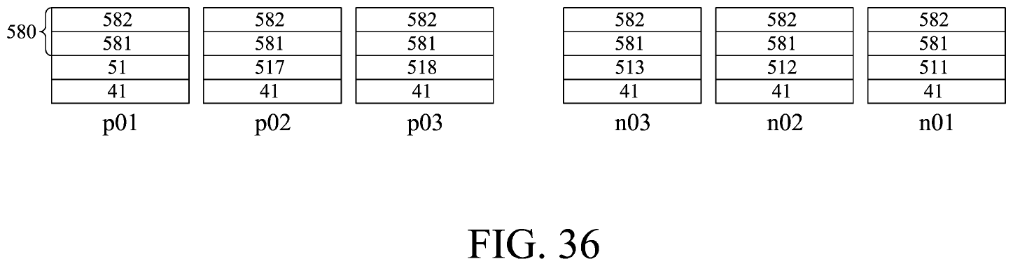

Referring to FIG. 26 and the example illustrated in FIG. 36, the method 200 proceeds to step 260, where an additional gate dielectric sub-layer 582 is formed on the gate dielectric sub-layer 581 at each of the first, second and third p-type regions p01, p02, p03, and the first, second and third n-type regions n01, n02, n03 using CVD, ALD, or other suitable deposition techniques. The materials, range of thickness, and configurations for the additional gate dielectric sub-layer 582 are similar to those for the gate dielectric sub-layer 581, and thus details thereof are omitted for the sake of brevity.

After step 260, as shown in FIG. 36, at each of the first, second and third p-type regions p01, p02, p03, and the first, second and third n-type regions n01, n02, n03, the gate dielectric sub-layer 581 and the additional gate dielectric sub-layer 582 are integrated into a gate dielectric layer 580. The materials, range of thickness, and configurations for the gate dielectric layer 580 are similar to those for the gate dielectric 58, and thus details thereof are omitted for the sake of brevity.

Referring to FIG. 26 and the example illustrated in FIG. 37, the method 200 proceeds to step 270, where a gate electrode 590 is formed on the gate dielectric layer 580 at each of the first, second and third p-type regions p01, p02, p03, and the first, second and third n-type regions n01, n02, n03, such that semiconductor devices 70 formed at the regions p01, p02, p03, n01, n02, n03 are obtained. Since step 270 is similar to step 160 described above with reference to FIG. 23, details thereof are omitted for the sake of brevity.

Referring to FIG. 37, since the semiconductor devices 70 at the first, second and third n-type regions n01, n02, n03 are similar to the semiconductor devices 30 described above with reference to FIG. 23, details thereof are omitted for the sake of brevity.

Referring to FIG. 37, the semiconductor devices 70 at the first, second and third n-type regions p01, p02, p03 are p-FETs. Similar to the semiconductor devices 30 at the regions p01, p02, p03 with reference to FIG. 23, in the case that the second dipole elements are Ga (or Zn), according to atomic concentrations of the second dipole elements in the interfacial layer 51 at the region p01 and the doped interfacial layer 517, 518 at each of the regions p02, p03 (i.e., the atomic concentrations of the second dipole elements in the doped interfacial layer or the interfacial layer: p03>p02>p01), the semiconductor device 70 at the region p01 would have a lower Vt value than that of the semiconductor device 70 at the region p02, and the semiconductor device 70 at the region p02 would have a lower Vt value than that of the semiconductor device 70 at the region p03 (i.e., the Vt value: p01<p02<p03). In the case that the second dipole elements in the doped interfacial layer 517, 518 at each of the regions p02, p03 is La (or Mg), the semiconductor device 70 at the region p01 would have a higher Vt value than that of the semiconductor device 70 at the region p02, and the semiconductor device 70 at the region p02 would have a higher Vt value than that of the semiconductor device 70 at the region p03 (i.e., the Vt value: p01>p02>p03).

In this disclosure, with the introduction of the dipole elements into the interfacial layer for at least one of the semiconductor devices, the semiconductor devices can have different threshold voltage values even when the gate electrodes of the semiconductor devices have the same configuration, have the same thickness, and are made of the same material. In the method of this disclosure, by varying species in the dipole layer, thickness of the dipole layer and thickness of the diffusion barrier layer, different atomic concentration of the dipole elements in the interfacial layer can be varied accordingly, thereby tuning the value of the threshold voltage of each of the semiconductor devices. In addition, the introduction of the dipole elements can be performed by the dipole-first and/or the dipole-last process. Therefore, the method in this disclosure provides a flexible strategy capable of obtaining the semiconductor devices which achieve multiple threshold voltage.

In accordance with some embodiments of the present disclosure, a semiconductor structure includes a plurality of semiconductor devices. Each of the semiconductor devices includes at least one channel layer, at least one interfacial layer, a gate dielectric layer, and dipole elements. The at least one interfacial layer is disposed on the at least one channel layer, and includes an insulating material. The gate dielectric layer is disposed over the at least one interfacial layer such that the at least one channel layer is separated from the gate dielectric layer through the at least one interfacial layer. The gate electrode is disposed on the gate dielectric layer. The dipole elements are present in the interfacial layer of at least one of the semiconductor devices in a predetermined amount such that the at least one of the semiconductor devices has a threshold voltage different from that of the other of the semiconductor devices.

In accordance with some embodiments of the present disclosure, the dipole elements include zinc (Zn), gallium (Ga), lanthanum (La), magnesium (Mg), or combinations thereof.

In accordance with some embodiments of the present disclosure, the gate electrodes of the semiconductor devices have the same thickness.

In accordance with some embodiments of the present disclosure, the atomic concentration of the dipole elements in the at least one interfacial layer ranges from 0.5% to 25%.

In accordance with some embodiments of the present disclosure, each of the semiconductor devices includes a plurality of the channel layers separated from each other and a plurality of the interfacial layers disposed respectively on the channel layers. The gate dielectric layer is disposed on the interfacial layers such that the channel layers are separated from the gate dielectric layer through the interfacial layers, respectively. Two adjacent ones of the channel layers are separated from each other by a distance ranging from 4 nm to 12 nm.

In accordance with some embodiments of the present disclosure, a method for manufacturing a semiconductor structure includes forming a plurality of patterned structures each having at least one channel layer, forming at least one interfacial layer on the at least one channel layer of each of the patterned structures, forming a gate dielectric layer over the at least one interfacial layer on each of the patterned structures such that the at least one channel layer is separated from the gate dielectric layer through the at least one interfacial layer, introducing dipole elements into the at least one interfacial layer on at least one of the patterned structures, and forming a gate electrode on the gate dielectric layer on each of the patterned structures. The interfacial layer includes an insulating material

In accordance with some embodiments of the present disclosure, the dipole elements include zinc (Zn), gallium (Ga), lanthanum (La), magnesium (Mg), or combinations thereof.

In accordance with some embodiments of the present disclosure, introduction of the dipole elements is performed before forming the gate dielectric layer, and includes forming a dipole layer on the at least one interfacial layer on each of the patterned structures, performing a thermal annealing process to permit the dipole elements in the dipole layer to diffuse into the at least one interfacial layer on each of the patterned structures, and removing the dipole layer. The dipole layer includes the dipole elements.

In accordance with some embodiments of the present disclosure, the dipole layer includes at least one dipole sub-layer. The at least one dipole sub-layer has a thickness ranging from 0.5 Å to 25 Å.

In accordance with some embodiments of the present disclosure, introduction of the dipole elements further includes forming a diffusion barrier layer between the dipole layer and the at least one interfacial layer on the at least one of the patterned structures to control distribution and an amount of the dipole elements in the at least one interfacial layer on the at least one of the patterned structures, and removing the diffusion barrier layer after the thermal annealing process.

In accordance with some embodiments of the present disclosure, the diffusion barrier layer includes an oxide, a nitride, a carbide, an oxynitride, an oxycarbide, a carbonitride, an oxycarbonitride, a metal oxide, a metal nitride, a metal carbide, a metal oxynitride, or combinations thereof.

In accordance with some embodiments of the present disclosure, the diffusion barrier layer includes at least one diffusion sub-layer. The at least one diffusion sub-layer has a thickness ranging from 5 Å to 50 Å.

In accordance with some embodiments of the present disclosure, introduction of the dipole elements further includes forming a capping layer on the dipole layer opposite to the at least one interfacial layer on the at least one of the patterned structures to stabilize the dipole elements during the thermal annealing process, and removing the capping layer after the thermal annealing process.

In accordance with some embodiments of the present disclosure, the capping layer includes an oxide, a nitride, a carbide, an oxynitride, an oxycarbide, a carbonitride, an oxycarbonitride, a metal oxide, a metal nitride, a metal carbide, a metal oxynitride, or combinations thereof.

In accordance with some embodiments of the present disclosure, the capping layer has a thickness ranging from 5 Å to 50 Å.

In accordance with some embodiments of the present disclosure, introduction of the dipole elements is performed after forming the gate dielectric layer, and includes forming a dipole layer on the gate dielectric layer on the at least one of the patterned structures, performing a thermal annealing process to permit the dipole elements in the dipole layer to diffuse into the at least one interfacial layer on the at least one of the patterned structures, and removing the dipole layer. The dipole layer includes the dipole elements.

In accordance with some embodiments of the present disclosure, each of the patterned structures includes a plurality of the channel layers. A plurality of the interfacial layers are respectively formed on the channel layers of each of the patterned structures. The gate dielectric layer is formed to permit the channel layers of each of the patterned structures to be separated from the gate dielectric layer through the interfacial layers, respectively. Two adjacent ones of the channel layers are separated from each other by a distance (D) ranging from 4 nm to 12 nm.

In accordance with some embodiments of the present disclosure, a method for manufacturing a semiconductor structure includes forming a plurality of patterned structures which respectively include channel layers, forming interfacial layers respectively on the channel layers of the patterned structures, forming a plurality of gate dielectric layers over the interfacial layers respectively on the patterned structures, forming a plurality of gate electrodes respectively on the gate dielectric layers such that, after forming the gate electrodes, the patterned structures are respectively formed into a plurality of semiconductor devices, and introducing dipole elements into at least one of the interfacial layers on at least one of the patterned structures before forming the gate electrodes, so as to permit the at least one of the semiconductor devices including the at least one of the patterned structures to have a threshold voltage different from that of the other of the semiconductor devices. Each of the interfacial layers includes an insulating material.

In accordance with some embodiments of the present disclosure, the gate electrodes of the semiconductor devices have the same thickness.

In accordance with some embodiments of the present disclosure, the dipole elements include zinc (Zn), gallium (Ga), lanthanum (La), magnesium (Mg), or combinations thereof.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a plurality of semiconductor devices, each including
at least one channel layer,
at least one interfacial layer disposed on the at least one channel layer and including an insulating material,
a gate dielectric layer disposed over the at least one interfacial layer such that the at least one channel layer is separated from the gate dielectric layer through the at least one interfacial layer, and
a gate electrode disposed on the gate dielectric layer; and
dipole elements present in the interfacial layer of at least one of the semiconductor devices in a predetermined amount such that the at least one of the semiconductor devices has a threshold voltage different from that of the other of the semiconductor devices.

2. The semiconductor structure of claim 1, wherein the dipole elements include zinc (Zn), gallium (Ga), lanthanum (La), magnesium (Mg), or combinations thereof.

3. The semiconductor structure of claim 1, wherein the gate electrodes of the semiconductor devices have the same thickness.

4. The semiconductor structure of claim 1, wherein the atomic concentration of the dipole elements in the at least one interfacial layer ranges from 0.5% to 25%.

5. The semiconductor structure of claim 1, wherein:
each of the semiconductor devices includes a plurality of the channel layers separated from each other, and a plurality of the interfacial layers disposed respectively on the channel layers;
the gate dielectric layer is disposed on the interfacial layers such that the channel layers are separated from the gate dielectric layer through the interfacial layers, respectively; and
two adjacent ones of the channel layers are separated from each other by a distance ranging from 4 nm to 12 nm.

6. A method for manufacturing a semiconductor structure, comprising:
forming a plurality of patterned structures each having at least one channel layer;
forming at least one interfacial layer on the at least one channel layer of each of the patterned structures, the interfacial layer including an insulating material;
forming a gate dielectric layer over the at least one interfacial layer on each of the patterned structures such that the at least one channel layer is separated from the gate dielectric layer through the at least one interfacial layer;
introducing dipole elements into the at least one interfacial layer on at least one of the patterned structures; and
forming a gate electrode on the gate dielectric layer on each of the patterned structures.

7. The method of claim 6, wherein the dipole elements include zinc (Zn), gallium (Ga), lanthanum (La), magnesium (Mg), or combinations thereof.

8. The method of claim 6, wherein introduction of the dipole elements is performed before forming the gate dielectric layer, and includes:
forming a dipole layer on the at least one interfacial layer on each of the patterned structures, the dipole layer including the dipole elements;
performing a thermal annealing process to permit the dipole elements in the dipole layer to diffuse into the at least one interfacial layer on each of the patterned structures; and
removing the dipole layer.

9. The method of claim 8, wherein the dipole layer includes at least one dipole sub-layer, the at least one dipole sub-layer having a thickness ranging from 0.5 Å to 25 Å.

10. The method of claim 8, wherein introduction of the dipole elements further includes:
forming a diffusion barrier layer between the dipole layer and the at least one interfacial layer on the at least one of the patterned structures to control distribution and an amount of the dipole elements in the at least one interfacial layer on the at least one of the patterned structures; and
removing the diffusion barrier layer after the thermal annealing process.

11. The method of claim 10, wherein the diffusion barrier layer includes an oxide, a nitride, a carbide, an oxynitride, an oxycarbide, a carbonitride, an oxycarbonitride, a metal oxide, a metal nitride, a metal carbide, a metal oxynitride, or combinations thereof.

12. The method of claim 10, wherein the diffusion barrier layer includes at least one diffusion sub-layer, the at least one diffusion sub-layer having a thickness ranging from 5 Å to 50 Å.

13. The method of claim 8, wherein introduction of the dipole elements further includes:
forming a capping layer on the dipole layer opposite to the at least one interfacial layer on the at least one of the patterned structures to stabilize the dipole elements during the thermal annealing process; and
removing the capping layer after the thermal annealing process.

14. The method of claim 13, wherein the capping layer includes an oxide, a nitride, a carbide, an oxynitride, an oxycarbide, a carbonitride, an oxycarbonitride, a metal oxide, a metal nitride, a metal carbide, a metal oxynitride, or combinations thereof.

15. The method of claim 13, wherein the capping layer has a thickness ranging from 5 Å to 50 Å.

16. The method of claim 6, wherein introduction of the dipole elements is performed after forming the gate dielectric layer, and includes:
forming a dipole layer on the gate dielectric layer on the at least one of the patterned structures, the dipole layer including the dipole elements;
performing a thermal annealing process to permit the dipole elements in the dipole layer to diffuse into the at least one interfacial layer on the at least one of the patterned structures; and
removing the dipole layer.

17. The method of claim 6, wherein:
each of the patterned structures includes a plurality of the channel layers;
a plurality of the interfacial layers are respectively formed on the channel layers of each of the patterned structures;
the gate dielectric layer is formed to permit the channel layers of each of the patterned structures to be separated from the gate dielectric layer through the interfacial layers, respectively; and
two adjacent ones of the channel layers are separated from each other by a distance ranging from 4 nm to 12 nm.

18. A method for manufacturing a semiconductor structure, comprising:
forming a plurality of patterned structures which respectively include channel layers;
forming interfacial layers respectively on the channel layers of the patterned structures, each of the interfacial layers including an insulating material;
forming a plurality of gate dielectric layers over the interfacial layers respectively on the patterned structures;
forming a plurality of gate electrodes respectively on the gate dielectric layers such that, after forming the gate electrodes, the patterned structures are respectively formed into a plurality of semiconductor devices; and
introducing dipole elements into at least one of the interfacial layers on at least one of the patterned structures before forming the gate electrodes, so as to permit the at least one of the semiconductor devices including the at least one of the patterned structures to have a threshold voltage different from that of the other of the semiconductor devices.

19. The method of claim 18, wherein the gate electrodes of the semiconductor devices have the same thickness.

20. The method of claim 18, wherein the dipole elements include zinc (Zn), gallium (Ga), lanthanum (La), magnesium (Mg), or combinations thereof.
